(19) United States
(12) Patent Application Publication
(10) Pub. No.: US 2026/0360301 A1
(43) Pub. Date: Nov. 12, 2026

(54) DISPLAY DEVICE AND ELECTRONIC DEVICE INCLUDING THE SAME

(71) Applicant: Samsung Display Co., LTD., Yongin-si (KR)

(72) Inventors: SUKYO JUNG, Yongin-si (KR); JAEWON CHO, Yongin-si (KR); HYUNJOON KIM, Yongin-si (KR); HAN-BYUL LIM, Yongin-si (KR)

(21) Appl. No.: 19/332,779

(22) Filed: Sep. 18, 2025

(30) Foreign Application Priority Data
May 9, 2025 (KR) 10-2025-0060275

(51) Int. Cl. G09G 3/32; H10H 29/32

(52) U.S. Cl. CPC G09G 3/32; H10H 29/32

(57) ABSTRACT

A display device includes: a pixel disposed in a display area, a 1-1 stage disposed at one side of the display area in a plan view, a 4-2 stage disposed at the one side of the display area in the plan view, and a 1-3 stage disposed at the one side of the display area in the plan view. The 1-3 stage may receive a 1-1 signal from the 1-1 stage through a 1-1 transfer line crossing the 4-2 stage in the plan view.

The application claims priority to Korean Patent Application No. 10-2025-0060275, filed on May 09, 2025, and all the benefits accruing therefrom under 35 U.S.C. §119, the content of which in its entirety is herein incorporated by reference.

### BACKGROUND

### 1. Field

The disclosure relates to a display device and an electronic device including the same. More particularly, the disclosure relates a display device providing visual information and an electronic device including the same.

### 2. Description of the Related Art

A display device displays an image for providing visual information to a user. Among display devices, an organic light-emitting display device is attracting attention.

The display device may include a display area in which pixels are located and a non-display area including a driver. The driver may generate a driving signal and provide the driving signal to the display area. For example, the driver may provide a gate signal, a light-emitting control signal, and/or the like to the display area.

### SUMMARY

Embodiments of the disclosure provide a display device with reduced dead space.

Embodiments of the disclosure provide an electronic device including the display device.

A display device in an embodiment of the disclosure includes a pixel disposed in a display area, a 1-1 stage disposed at one side of the display area in a plan view, a 4-2 stage disposed at the one side of the display area in the plan view, and a 1-3 stage disposed at the one side of the display area in the plan view.

In an embodiment, the 1-3 stage may receive a 1-1 signal from the 1-1 stage through a 1-1 transfer line crossing the 4-2 stage in the plan view.

In an embodiment, the display device may further include a 1-2 stage disposed at an opposite side of the display area in the plan view, a 4-1 stage disposed at the opposite side of the display area in the plan view, and a 4-3 stage disposed at the opposite side of the display area in the plan view, and receiving a 4-1 signal from the 4-1 stage through a 4-1 transfer line crossing the 1-2 stage in the plan view.

In an embodiment, the 1-1 stage may output the 1-1 signal to the pixel.

In an embodiment, the 1-1 transfer line may at least partially overlap a transistor included in the 4-2 stage in the plan view.

In an embodiment, the 4-2 stage may include a lower metal layer, a first active layer disposed on the lower metal layer, a first gate layer disposed on the first active layer, and a second gate layer disposed on the first gate layer, and the 1-1 transfer line may be disposed on the second gate layer.

In an embodiment, the 1-1 transfer line may cross a lower metal pattern included in the lower metal layer in the plan view.

In an embodiment, the 1-1 transfer line may cross an active pattern included in the first active layer in the plan view.

In an embodiment, the 1-1 transfer line may cross a gate pattern included in the first gate layer in the plan view.

In an embodiment, the 1-1 transfer line may cross a gate pattern included in the second gate layer in the plan view.

In an embodiment, the display device may further include a second active layer disposed on the second gate layer and a third gate layer disposed on the second active layer, and the 1-1 transfer line is disposed on the third gate layer.

In an embodiment, the 1-1 transfer line may cross a portion of gate patterns included in the third gate layer in the plan view.

In an embodiment, the 4-2 stage may be disposed between the 1-1 stage and the 1-3 stage.

In an embodiment, the 1-1 stage and the 4-2 stage may be disposed along a second direction, and the 1-1 transfer line may extend in the second direction.

A display device in an embodiment of the disclosure includes a pixel disposed in a display area, and the pixel including a lower active pattern, a first gate electrode disposed on the lower active pattern, a second gate electrode disposed on the first gate electrode, an upper active pattern disposed on the second gate electrode, and a third gate electrode disposed on the upper active pattern, a 1-1 stage disposed at one side of the display area in a plan view, a 4-2 stage disposed at the one side of the display area in the plan view, and a 1-3 stage disposed at the one side of the display area in the plan view.

In an embodiment, the 1-3 stage may receive a 1-1 signal from the 1-1 stage through a 1-1 transfer line crossing the 4-2 stage in the plan view.

In an embodiment, the 4-2 stage may include a first active layer disposed in a same layer as the lower active pattern, a first gate layer disposed in a same layer as the first gate electrode, a second gate layer disposed in a same layer as the second gate electrode, and a third gate layer disposed in a same layer as the third gate electrode, and the 1-1 transfer line may be disposed on the third gate layer.

In an embodiment, the 1-1 transfer line may cross an active pattern included in the first active layer in the plan view.

In an embodiment, the 1-1 transfer line may cross a gate pattern included in the first gate layer in the plan view.

In an embodiment, the 1-1 transfer line may cross a gate pattern included in the second gate layer in the plan view.

In an embodiment, the 1-1 transfer line may cross a gate pattern included in the third gate layer in the plan view.

An electronic device in an embodiment of the disclosure includes a pixel disposed in a display area, a 1-1 stage disposed at one side of the display area in a plan view, a 4-2 stage disposed at the one side of the display area in the plan view, a 1-3 stage disposed at the one side of the display area in the plan view, and a display module receiving a data signal and a control signal from a processor.

In an embodiment, wherein the 1-3 stage may receive a 1-1 signal from the 1-1 stage through a 1-1 transfer line crossing the 4-2 stage in the plan view.

In an embodiment, the 1-1 signal may be output to the pixel.

A display device in embodiments may include a pixel disposed in a display area, a 1-1 stage disposed at one side of the display area in a plan view, a 4-2 stage disposed at the one side of the display area in the plan view, and a 1-3 stage disposed at the one side of the display area in the plan view. The 1-3 stage may receive a 1-1 signal from the 1-1 stage through a 1-1 transfer line crossing the 4-2 stage in the plan view.

Accordingly, a dead space of the display device may be reduced. For example, an area of a non-display area may be reduced.

### BRIEF DESCRIPTION OF THE DRAWINGS

Illustrative, non-limiting embodiments will be more clearly understood from the following detailed description in conjunction with the accompanying drawings.

FIG. 1 is a plan view illustrating an embodiment of a display device.

FIG. 2 is a block diagram illustrating the display device of FIG. 1.

FIG. 3 is a block diagram illustrating a partial area of the display device of FIG. 2.

FIG. 4 is a block diagram illustrating a partial area of the display device of FIG. 2.

FIG. 5 is a block diagram illustrating a display area and a first driver included in the display device of FIG. 2.

FIG. 6 is a block diagram illustrating a display area and a second driver included in the display device of FIG. 2.

FIG. 7 is a block diagram illustrating a display area and a third driver included in the display device of FIG. 2.

FIG. 8 is a block diagram illustrating a display area and a fourth driver included in the display device of FIG. 2.

FIG. 9 is a circuit diagram illustrating the drivers included in the display device of FIG. 2.

FIGS. 10, 11, 12, 13, 14, 15, 16, 17, 18, 19, 20, and 21, are plan views illustrating a partial area of the display device of FIG. 1.

FIG. 22 is a cross-sectional view taken along line I-I` of the display device of FIG. 21.

FIG. 23 is a circuit diagram illustrating a pixel included in the display device of FIG. 1.

FIG. 24 is a cross-sectional view illustrating a portion of the pixel included in the display device of FIG. 1.

FIG. 25 is a block diagram illustrating an embodiment of an electronic device.

FIG. 26 is a schematic diagram of embodiments of an electronic device.

### DETAILED DESCRIPTION

Hereinafter, display devices in embodiments will be described in more detail with reference to the accompanying drawings. The same reference numerals are used for the same components in the drawings, and redundant descriptions of the same components will be omitted.

It will be understood that when an element is referred to as being “on” another element, it may be directly on the other element or intervening elements may be present therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, the singular forms “a,” “an,” and “the” are intended to include the plural forms, including “at least one,” unless the content clearly indicates otherwise. “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower,” may therefore, encompasses both an orientation of “lower” and “upper,” depending on the particular orientation of the figure. Similarly, if the device in one of the figures is turned over, elements described as “below” or “beneath” other elements would then be oriented “above” the other elements. The exemplary terms “below” or “beneath” may, therefore, encompass both an orientation of above and below.

"About" or "approximately" as used herein is inclusive of the stated value and means within an acceptable range of deviation for the particular value as determined by one of ordinary skill in the art, considering the measurement in question and the error associated with measurement of the particular quantity (i.e., the limitations of the measurement system). The term such as "about" may mean within one or more standard deviations, or within ± 30%, 20%, 10%, 5% of the stated value, for example.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

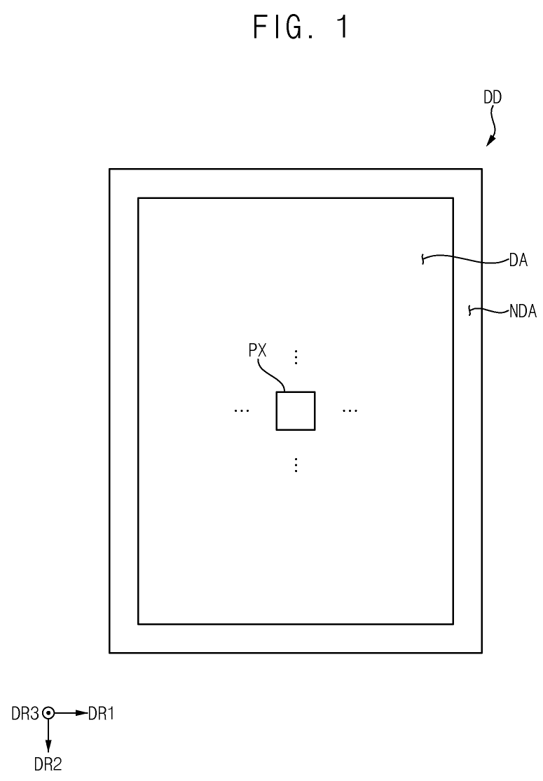

FIG. 1 is a plan view illustrating an embodiment of a display device.

Referring to FIG. 1, a display device DD in embodiments may include a display area DA and a non-display area NDA.

The display area DA may be defined as an area capable of displaying an image by generating light or adjusting transmittance of light provided from an external light source. The non-display area NDA may be an area that does not display an image. In addition, the non-display area NDA may surround at least a portion of the display area DA. In an embodiment, the non-display area NDA may surround an entirety of the display area DA, for example.

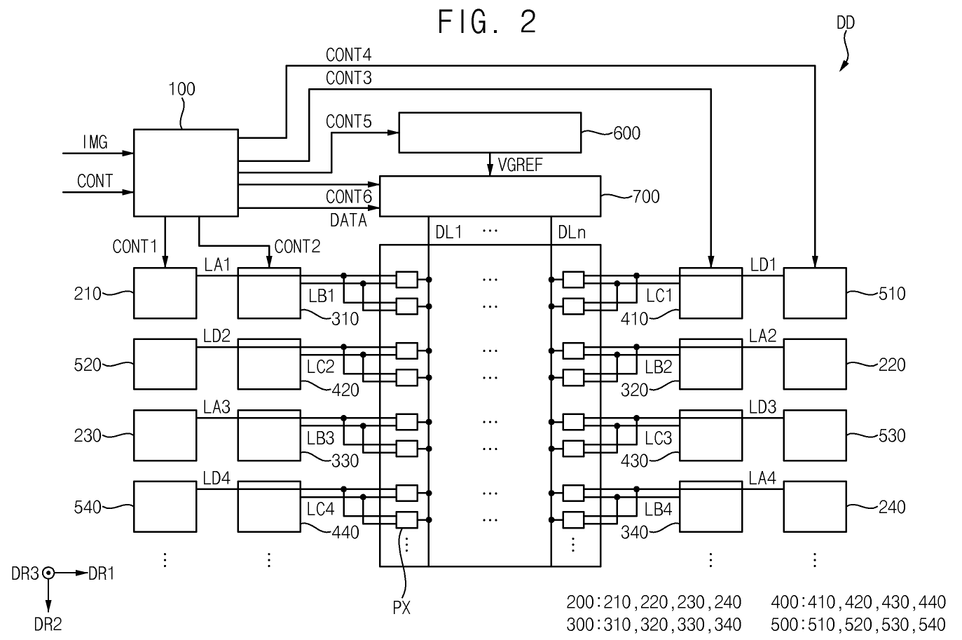

A plurality of pixels PX may be arranged in the display area DA. The plurality of pixels PX may be repeatedly arranged along a first direction DR1 and a second direction DR2 crossing the first direction DR1. A plurality of drivers may be disposed in the non-display area NDA. The plurality of drivers will be described later with reference to FIG. 2.

In an embodiment, the first direction DR1 and the second direction DR2 crossing the first direction DR1 may be defined. In an embodiment, the second direction DR2 may be substantially perpendicular to the first direction DR1, for example. However, this disclosure is not necessarily limited thereto, and the second direction DR2 may form an acute angle or an obtuse angle with the first direction DR1. In addition, a third direction DR3 crossing a plane formed by the first direction DR1 and the second direction DR2 may be defined. In an embodiment, the third direction DR3 may be substantially perpendicular to the plane formed by the first direction DR1 and the second direction DR2, for example. However, this disclosure is not necessarily limited thereto, and the third direction DR3 may form an acute angle or an obtuse angle with the plane formed by the first direction DR1 and the second direction DR2.

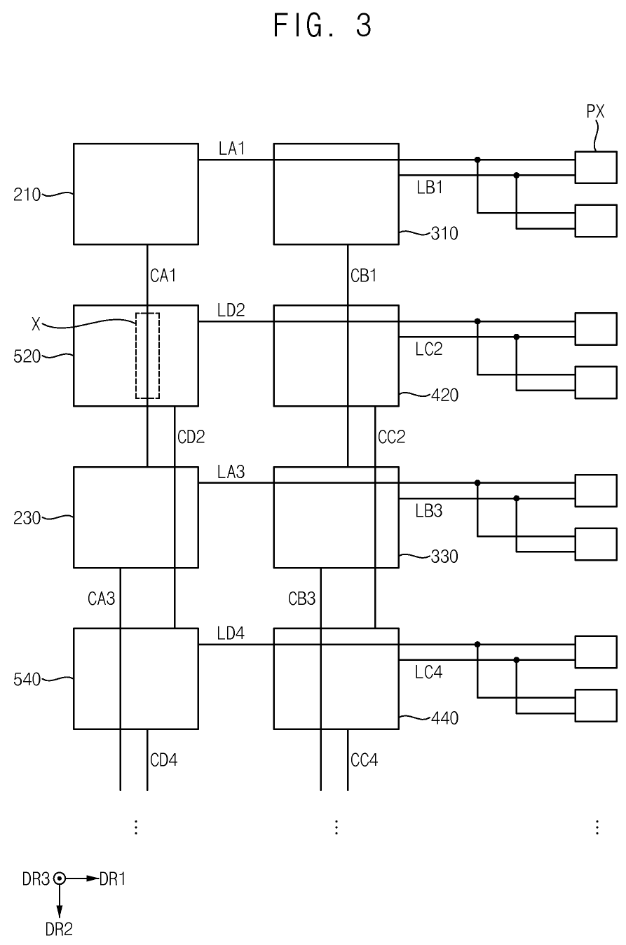

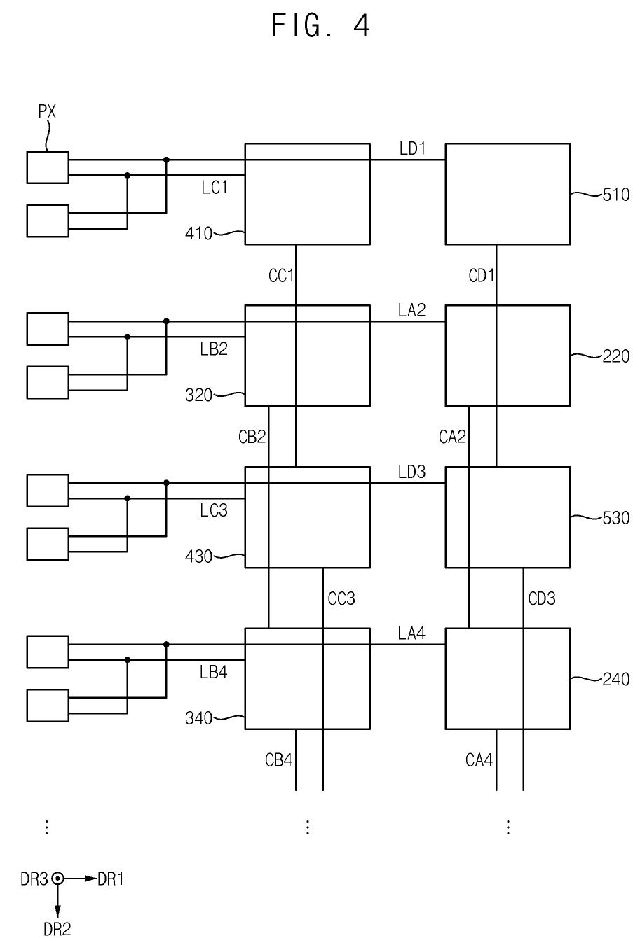

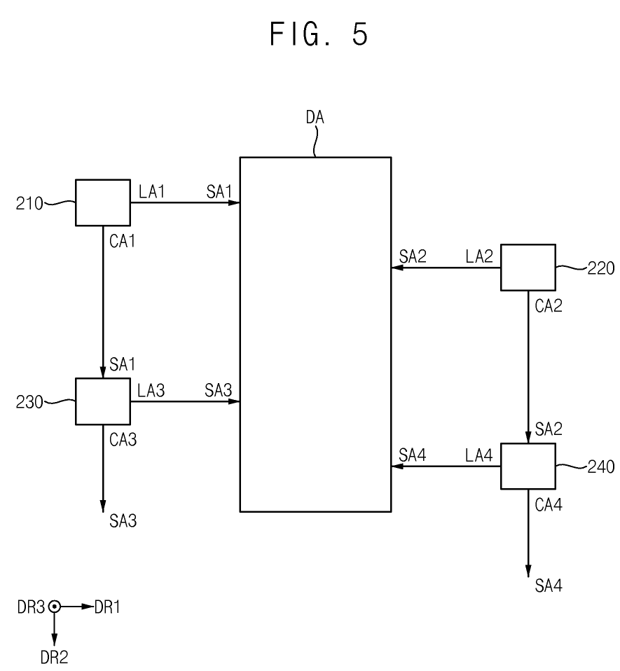

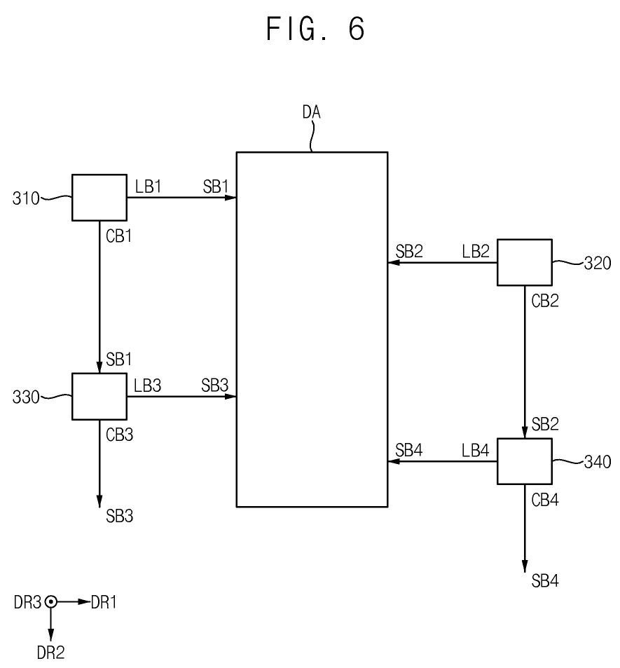

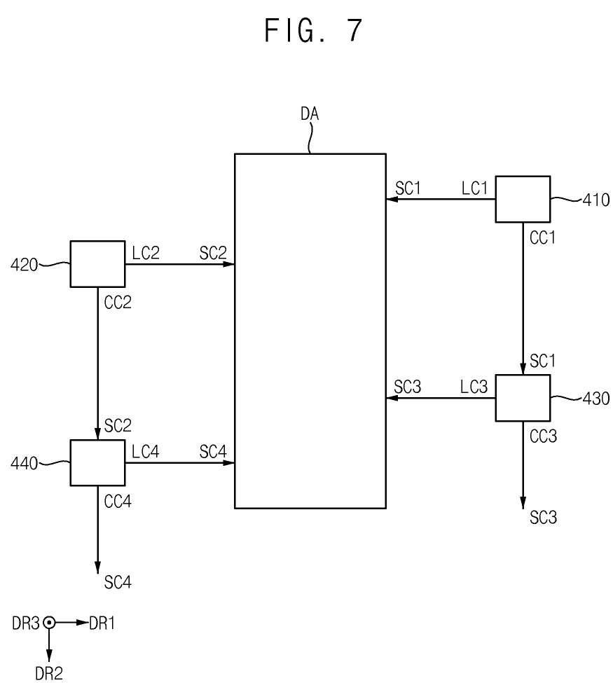

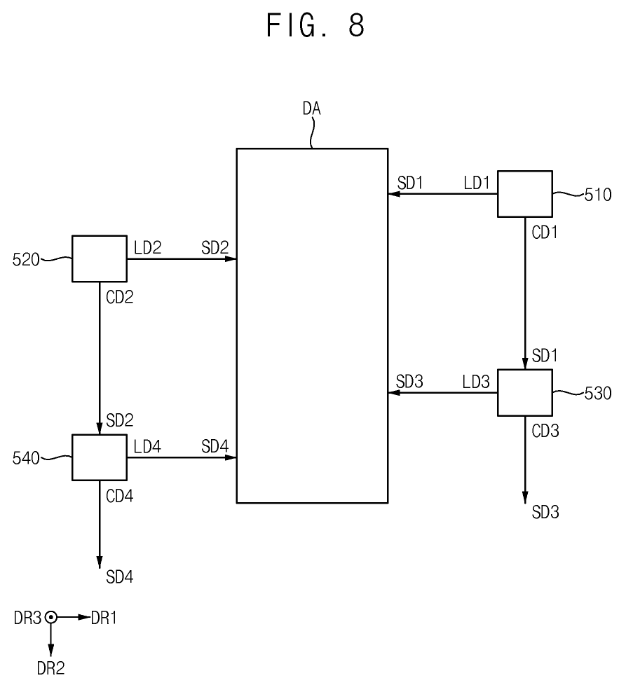

FIG. 2 is a block diagram illustrating the display device of FIG. 1. FIG. 3 is a block diagram illustrating a partial area of the display device of FIG. 2. FIG. 4 is a block diagram illustrating a partial area of the display device of FIG. 2. FIG. 5 is a block diagram illustrating a display area and a first driver included in the display device of FIG. 2. FIG. 6 is a block diagram illustrating a display area and a second driver included in the display device of FIG. 2. FIG. 7 is a block diagram illustrating a display area and a third driver included in the display device of FIG. 2. FIG. 8 is a block diagram illustrating a display area and a fourth driver included in the display device of FIG. 2.

Specifically, FIG. 3 is a block diagram illustrating stages disposed at one side of the display area DA, and FIG. 4 is a block diagram illustrating stages disposed at an opposite side of the display area DA.

Referring to FIG. 2, the plurality of drivers may include a driving controller 100, a first driver 200, a second driver 300, a third driver 400, a fourth driver 500, a gamma reference voltage generator 600, and a data driver 700. The plurality of pixels PX may be electrically connected to the driving controller 100, the first driver 200, the second driver 300, the third driver 400, the fourth driver 500, the gamma reference voltage generator 600, and the data driver 700.

The driving controller 100 may receive input image data IMG and an input control signal CONT from an external device. In an embodiment, the input image data IMG may include red image data, green image data, and blue image data. In another embodiment, the input image data IMG may include white image data. In another embodiment, the input image data IMG may include magenta image data, yellow image data, and cyan image data. The input control signal CONT may include a master clock signal, a data enable signal, and/or the like. The input control signal CONT may further include a vertical synchronization signal and a horizontal synchronization signal.

The driving controller 100 may receive the input image data IMG and the input control signal CONT and may generate a first control signal CONT1, a second control signal CONT2, a third control signal CONT3, a fourth control signal CONT4, a fifth control signal CONT5, a sixth control signal CONT6, and a data signal DATA.

The driving controller 100 may receive the input control signal CONT and may generate the first control signal CONT1. The driving controller 100 may output the first control signal CONT1 to the first driver 200. In an embodiment, the driving controller 100 may output the first control signal CONT1 to a 1-1 stage 210, for example.

The driving controller 100 may receive the input control signal CONT and may generate the second control signal CONT2. The driving controller 100 may output the second control signal CONT2 to the second driver 300. In an embodiment, the driving controller 100 may output the second control signal CONT2 to a 2-1 stage 310, for example.

The driving controller 100 may receive the input control signal CONT and may generate the third control signal CONT3. The driving controller 100 may output the third control signal CONT3 to the third driver 400. In an embodiment, the driving controller 100 may output the third control signal CONT3 to a 3-1 stage 410, for example.

The driving controller 100 may receive the input control signal CONT and may generate the fourth control signal CONT4. The driving controller 100 may output the fourth control signal CONT4 to the fourth driver 500. In an embodiment, the driving controller 100 may output the fourth control signal CONT4 to a 4-1 stage 510, for example.

The driving controller 100 may receive the input control signal CONT and may generate the fifth control signal CONT5. The driving controller 100 may output the fifth control signal CONT5 to the gamma reference voltage generator 600.

The driving controller 100 may receive the input control signal CONT and may generate the sixth control signal CONT6. In addition, the driving controller 100 may receive the input image data IMG and may generate the data signal DATA. The driving controller 100 may output the sixth control signal CONT6 and the data signal DATA to the data driver 700.

The gamma reference voltage generator 600 may generate a gamma reference voltage VGREF in response to the fifth control signal CONT5 received from the driving controller 100. The gamma reference voltage generator 600 may provide the gamma reference voltage VGREF to the data driver 700. The gamma reference voltage VGREF may have a value corresponding to the data signal DATA.

The data driver 700 may receive the sixth control signal CONT6 and the data signal DATA from the driving controller 100. In addition, the data driver 700 may receive the gamma reference voltage VGREF from the gamma reference voltage generator 600. The data driver 700 may convert the data signal DATA into an analog-type data voltage using the gamma reference voltage VGREF. The data driver 700 may provide the data voltage to the plurality of pixels PX. In an embodiment, the data driver 700 may provide the data voltage to pixels arranged in a first column among the plurality of pixels PX through a first data line DL1, for example. In addition, the data driver 700 may provide the data voltage to pixels arranged in an n-th column among the plurality of pixels PX through an n-th data line DLn.

Referring to FIGS. 3, 4, and 5, the first driver 200 may include a plurality of stages. In an embodiment, the first driver 200 may include a 1-1 stage 210, a 1-2 stage 220, a 1-3 stage 230, and a 1-4 stage 240, for example.

The 1-1 stage 210 may output a 1-1 signal SA1 to the display area DA through a 1-1 output line LA1. The 1-1 stage 210 may output the 1-1 signal SA1 to the plurality of pixels PX through the 1-1 output line LA1. In an embodiment, the 1-1 stage 210 may output the 1-1 signal SA1 to two pixel rows through the 1-1 output line LA1, for example, but this disclosure is not necessarily limited thereto. The 1-1 output line LA1 may extend in the first direction DR1.

The 1-2 stage 220 may output a 1-2 signal SA2 to the display area DA through a 1-2 output line LA2. The 1-2 stage 220 may output the 1-2 signal SA2 to the plurality of pixels PX through the 1-2 output line LA2. In an embodiment, the 1-2 stage 220 may output the 1-2 signal SA2 to two pixel rows through the 1-2 output line LA2, for example, but this disclosure is not necessarily limited thereto. The 1-2 output line LA2 may extend in the first direction DR1.

The 1-3 stage 230 may output a 1-3 signal SA3 to the display area DA through a 1-3 output line LA3. The 1-3 stage 230 may output the 1-3 signal SA3 to the plurality of pixels PX through the 1-3 output line LA3. In an embodiment, the 1-3 stage 230 may output the 1-3 signal SA3 to two pixel rows through the 1-3 output line LA3, for example, but this disclosure is not necessarily limited thereto. The 1-3 output line LA3 may extend in the first direction DR1.

The 1-4 stage 240 may output a 1-4 signal SA4 to the display area DA through a 1-4 output line LA4. The 1-4 stage 240 may output the 1-4 signal SA4 to the plurality of pixels PX through the 1-4 output line LA4. In an embodiment, the 1-4 stage 240 may output the 1-4 signal SA4 to two pixel rows through the 1-4 output line LA4, for example, but this disclosure is not necessarily limited thereto. The 1-4 output line LA4 may extend in the first direction DR1.

In an embodiment, the 1-1 signal SA1 and the 1-3 signal SA3 may be sequentially output. In an embodiment, after the 1-1 signal SA1 is output to the display area DA, the 1-3 signal SA3 may be output to the display area DA, for example, but this disclosure is not necessarily limited thereto. In an embodiment, the 1-2 signal SA2 and the 1-4 signal SA4 may be sequentially output. In an embodiment, after the 1-2 signal SA2 is output to the display area DA, the 1-4 signal SA4 may be output to the display area DA, for example, but this disclosure is not necessarily limited thereto.

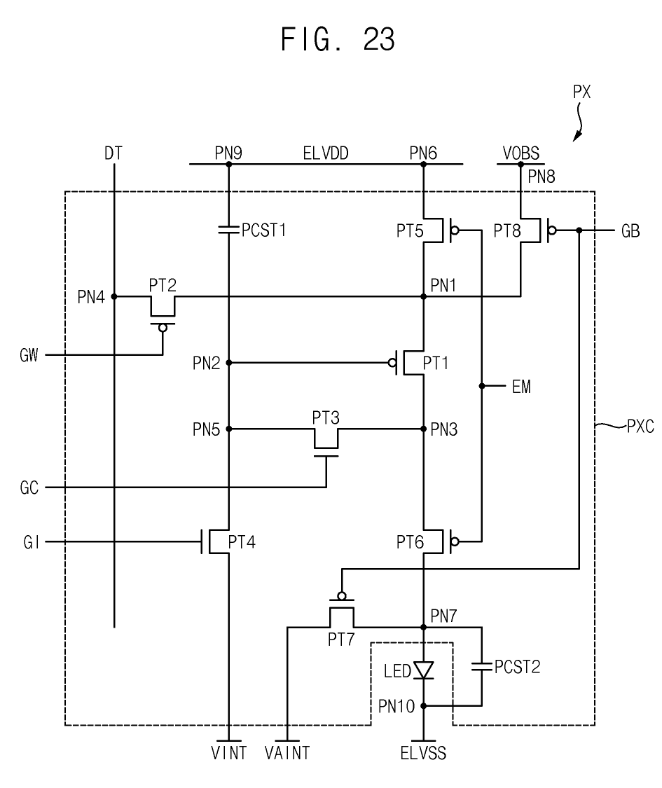

The first driver 200 may output a first signal to the display area DA. In an embodiment, the first driver 200 may output the first signal to the plurality of pixels PX, for example. Each of the 1-1 signal SA1, the 1-2 signal SA2, the 1-3 signal SA3, and the 1-4 signal SA4 may correspond to the first signal. In an embodiment, the first signal may be a light-emitting control signal (e.g., a light-emitting control signal EM of FIG. 23), and the first driver 200 may be a light-emitting control driver, but this disclosure is not necessarily limited thereto.

Referring to FIGS. 3, 4, and 6, the second driver 300 may include a plurality of stages. In an embodiment, the second driver 300 may include a 2-1 stage 310, a 2-2 stage 320, a 2-3 stage 330, and a 2-4 stage 340, for example.

The 2-1 stage 310 may output a 2-1 signal SB1 to the display area DA through a 2-1 output line LB1. The 2-1 stage 310 may output the 2-1 signal SB1 to the plurality of pixels PX through the 2-1 output line LB1. In an embodiment, the 2-1 stage 310 may output the 2-1 signal SB1 to two pixel rows through the 2-1 output line LB1, for example, but this disclosure is not necessarily limited thereto. The 2-1 output line LB1 may extend in the first direction DR1.

The 2-2 stage 320 may output a 2-2 signal SB2 to the display area DA through a 2-2 output line LB2. The 2-2 stage 320 may output the 2-2 signal SB2 to the plurality of pixels PX through the 2-2 output line LB2. In an embodiment, the 2-2 stage 320 may output the 2-2 signal SB2 to two pixel rows through the 2-2 output line LB2, for example, but this disclosure is not necessarily limited thereto. The 2-2 output line LB2 may extend in the first direction DR1.

The 2-3 stage 330 may output a 2-3 signal SB3 to the display area DA through a 2-3 output line LB3. The 2-3 stage 330 may output the 2-3 signal SB3 to the plurality of pixels PX through the 2-3 output line LB3. In an embodiment, the 2-3 stage 330 may output the 2-3 signal SB3 to two pixel rows through the 2-3 output line LB3, for example, but this disclosure is not necessarily limited thereto. The 2-3 output line LB3 may extend in the first direction DR1.

The 2-4 stage 340 may output a 2-4 signal SB4 to the display area DA through a 2-4 output line LB4. The 2-4 stage 340 may output the 2-4 signal SB4 to the plurality of pixels PX through the 2-4 output line LB4. In an embodiment, the 2-4 stage 340 may output the 2-4 signal SB4 to two pixel rows through the 2-4 output line LB4, for example, but this disclosure is not necessarily limited thereto. The 2-4 output line LB4 may extend in the first direction DR1.

In an embodiment, the 2-1 signal SB1 and the 2-3 signal SB3 may be sequentially output. In an embodiment, after the 2-1 signal SB1 is output to the display area DA, the 2-3 signal SB3 may be output to the display area DA, for example, but this disclosure is not necessarily limited thereto. In an embodiment, the 2-2 signal SB2 and the 2-4 signal SB4 may be sequentially output. In an embodiment, after the 2-2 signal SB2 is output to the display area DA, the 2-4 signal SB4 may be output to the display area DA, for example, but this disclosure is not necessarily limited thereto.

The second driver 300 may output a second signal to the display area DA. In an embodiment, the second driver 300 may output the second signal to the plurality of pixels PX, for example. Each of the 2-1 signal SB1, the 2-2 signal SB2, the 2-3 signal SB3, and the 2-4 signal SB4 may correspond to the second signal. In an embodiment, the second signal may be a gate initialization signal (e.g., a gate initialization signal GI of FIG. 23), and the second driver 300 may be a gate initialization driver, but this disclosure is not necessarily limited thereto.

Referring to FIGS. 3, 4, and 7, the third driver 400 may include a plurality of stages. In an embodiment, the third driver 400 may include a 3-1 stage 410, a 3-2 stage 420, a 3-3 stage 430, and a 3-4 stage 440, for example.

The 3-1 stage 410 may output a 3-1 signal SC1 to the display area DA through a 3-1 output line LC1. The 3-1 stage 410 may output the 3-1 signal SC1 to the plurality of pixels PX through the 3-1 output line LC1. In an embodiment, the 3-1 stage 410 may output the 3-1 signal SC1 to two pixel rows through the 3-1 output line LC1, for example, but this disclosure is not necessarily limited thereto. The 3-1 output line LC1 may extend in the first direction DR1.

The 3-2 stage 420 may output a 3-2 signal SC2 to the display area DA through a 3-2 output line LC2. The 3-2 stage 420 may output the 3-2 signal SC2 to the plurality of pixels PX through the 3-2 output line LC2. In an embodiment, the 3-2 stage 420 may output the 3-2 signal SC2 to two pixel rows through the 3-2 output line LC2, for example, but this disclosure is not necessarily limited thereto. The 3-2 output line LC2 may extend in the first direction DR1.

The 3-3 stage 430 may output a 3-3 signal SC3 to the display area DA through a 3-3 output line LC3. The 3-3 stage 430 may output the 3-3 signal SC3 to the plurality of pixels PX through the 3-3 output line LC3. In an embodiment, the 3-3 stage 430 may output the 3-3 signal SC3 to two pixel rows through the 3-3 output line LC3, for example, but this disclosure is not necessarily limited thereto. The 3-3 output line LC3 may extend in the first direction DR1.

The 3-4 stage 440 may output a 3-4 signal SC4 to the display area DA through a 3-4 output line LC4. The 3-4 stage 440 may output the 3-4 signal SC4 to the plurality of pixels PX through the 3-4 output line LC4. In an embodiment, the 3-4 stage 440 may output the 3-4 signal SC4 to two pixel rows through the 3-4 output line LC4, for example, but this disclosure is not necessarily limited thereto. The 3-4 output line LC4 may extend in the first direction DR1.

In an embodiment, the 3-1 signal SC1 and the 3-3 signal SC3 may be sequentially output. In an embodiment, after the 3-1 signal SC1 is output to the display area DA, the 3-3 signal SC3 may be output to the display area DA, for example, but this disclosure is not necessarily limited thereto. In an embodiment, the 3-2 signal SC2 and the 3-4 signal SC4 may be sequentially output. In an embodiment, after the 3-2 signal SC2 is output to the display area DA, the 3-4 signal SC4 may be output to the display area DA, for example, but this disclosure is not necessarily limited thereto.

The third driver 400 may output a third signal to the display area DA. In an embodiment, the third driver 400 may output the third signal to the plurality of pixels PX, for example. Each of the 3-1 signal SC1, the 3-2 signal SC2, the 3-3 signal SC3, and the 3-4 signal SC4 may correspond to the third signal. In an embodiment, the third signal may be a gate compensation signal (e.g., a gate compensation signal GC of FIG. 23), and the third driver 400 may be a gate compensation driver, but this disclosure is not necessarily limited thereto.

Referring to FIGS. 3, 4, and 8, the fourth driver 500 may include a plurality of stages. In an embodiment, the fourth driver 500 may include a 4-1 stage 510, a 4-2 stage 520, a 4-3 stage 530, and a 4-4 stage 540, for example.

The 4-1 stage 510 may output a 4-1 signal SD1 to the display area DA through a 4-1 output line LD1. The 4-1 stage 510 may output the 4-1 signal SD1 to the plurality of pixels PX through the 4-1 output line LD1. In an embodiment, the 4-1 stage 510 may output the 4-1 signal SD1 to two pixel rows through the 4-1 output line LD1, for example, but this disclosure is not necessarily limited thereto. The 4-1 output line LD1 may extend in the first direction DR1.

The 4-2 stage 520 may output a 4-2 signal SD2 to the display area DA through a 4-2 output line LD2. The 4-2 stage 520 may output the 4-2 signal SD2 to the plurality of pixels PX through the 4-2 output line LD2. In an embodiment, the 4-2 stage 520 may output the 4-2 signal SD2 to two pixel rows through the 4-2 output line LD2, for example, but this disclosure is not necessarily limited thereto. The 4-2 output line LD2 may extend in the first direction DR1.

The 4-3 stage 530 may output a 4-3 signal SD3 to the display area DA through a 4-3 output line LD3. The 4-3 stage 530 may output the 4-3 signal SD3 to the plurality of pixels PX through the 4-3 output line LD3. In an embodiment, the 4-3 stage 530 may output the 4-3 signal SD3 to two pixel rows through the 4-3 output line LD3, for example, but this disclosure is not necessarily limited thereto. The 4-3 output line LD3 may extend in the first direction DR1.

The 4-4 stage 540 may output a 4-4 signal SD4 to the display area DA through a 4-4 output line LD4. The 4-4 stage 540 may output the 4-4 signal SD4 to the plurality of pixels PX through the 4-4 output line LD4. In an embodiment, the 4-4 stage 540 may output the 4-4 signal SD4 to two pixel rows through the 4-4 output line LD4, for example, but this disclosure is not necessarily limited thereto. The 4-4 output line LD4 may extend in the first direction DR1.

In an embodiment, the 4-1 signal SD1 and the 4-3 signal SD3 may be sequentially output. In an embodiment, after the 4-1 signal SD1 is output to the display area DA, the 4-3 signal SD3 may be output to the display area DA, for example, but this disclosure is not necessarily limited thereto. In an embodiment, the 4-2 signal SD2 and the 4-4 signal SD4 may be sequentially output. In an embodiment, after the 4-2 signal SD2 is output to the display area DA, the 4-4 signal SD4 may be output to the display area DA, for example, but this disclosure is not necessarily limited thereto.

The fourth driver 500 may output a fourth signal to the display area DA. In an embodiment, the fourth driver 500 may output the fourth signal to the plurality of pixels PX, for example. Each of the 4-1 signal SD1, the 4-2 signal SD2, the 4-3 signal SD3, and the 4-4 signal SD4 may correspond to the fourth signal. In an embodiment, the fourth signal may be a gate bias signal (e.g., a gate bias signal GB of FIG. 23), and the fourth driver 500 may be a gate bias driver, but this disclosure is not necessarily limited thereto.

Referring to FIGS. 2, 3, and 4, in embodiments, the 1-1 stage 210 and the 1-3 stage 230 may be disposed at one side of the display area DA in a plan view, and the 1-2 stage 220 and the 1-4 stage 240 may be disposed at an opposite side of the display area DA. In an embodiment, the 1-1 stage 210 and the 1-3 stage 230 may be spaced apart from the display area DA in a direction opposite to the first direction DR1, and the 1-2 stage 220 and the 1-4 stage 240 may be spaced apart from the display area DA in the first direction DR1, for example.

In an embodiment, the 2-1 stage 310 and the 2-3 stage 330 may be disposed at the one side of the display area DA, and the 2-2 stage 320 and the 2-4 stage 340 may be disposed at an opposite side of the display area DA. In an embodiment, the 2-1 stage 310 and the 2-3 stage 330 may be spaced apart from the display area DA in a direction opposite to the first direction DR1, and the 2-2 stage 320 and the 2-4 stage 340 may be spaced apart from the display area DA in the first direction DR1, for example.

In an embodiment, the 2-1 stage 310 may be disposed between the 1-1 stage 210 and the display area DA. In an embodiment, the 2-1 stage 310 may be spaced apart from the 1-1 stage 210 in the first direction DR1, for example. In an embodiment, the 2-2 stage 320 may be disposed between the 1-2 stage 220 and the display area DA. In an embodiment, the 2-2 stage 320 may be spaced apart from the 1-2 stage 220 in a direction opposite to the first direction DR1, for example. In an embodiment, the 2-3 stage 330 may be disposed between the 1-3 stage 230 and the display area DA. In an embodiment, the 2-3 stage 330 may be spaced apart from the 1-3 stage 230 in the first direction DR1, for example. In an embodiment, the 2-4 stage 340 may be disposed between the 1-4 stage 240 and the display area DA. In an embodiment, the 2-4 stage 340 may be spaced apart from the 1-4 stage 240 in a direction opposite to the first direction DR1, for example.

In an embodiment, the 3-1 stage 410 and the 3-3 stage 430 may be disposed at an opposite side of the display area DA in the plan view, and the 3-2 stage 420 and the 3-4 stage 440 may be disposed at the one side of the display area DA. In an embodiment, the 3-1 stage 410 and the 3-3 stage 430 may be spaced apart from the display area DA in the first direction DR1, and the 3-2 stage 420 and the 3-4 stage 440 may be spaced apart from the display area DA in a direction opposite to the first direction DR1, for example.

In an embodiment, the 3-1 stage 410 may be disposed between the 4-1 stage 510 and the display area DA. In an embodiment, the 3-1 stage 410 may be spaced apart from the 4-1 stage 510 in a direction opposite to the first direction DR1, for example. In an embodiment, the 3-2 stage 420 may be disposed between the 4-2 stage 520 and the display area DA. In an embodiment, the 3-2 stage 420 may be spaced apart from the 4-2 stage 520 in the first direction DR1, for example. In an embodiment, the 3-3 stage 430 may be disposed between the 4-3 stage 530 and the display area DA. In an embodiment, the 3-3 stage 430 may be spaced apart from the 4-3 stage 530 in a direction opposite to the first direction DR1, for example. In an embodiment, the 3-4 stage 440 may be disposed between the 4-4 stage 540 and the display area DA. In an embodiment, the 3-4 stage 440 may be spaced apart from the 4-4 stage 540 in the first direction DR1, for example.

In an embodiment, the 4-1 stage 510 and the 4-3 stage 530 may be disposed at an opposite side of the display area DA in the plan view, and the 4-2 stage 520 and the 4-4 stage 540 may be disposed at the one side of the display area DA. In an embodiment, the 4-1 stage 510 and the 4-3 stage 530 may be spaced apart from the display area DA in the first direction DR1, and the 4-2 stage 520 and the 4-4 stage 540 may be spaced apart from the display area DA in a direction opposite to the first direction DR1, for example.

In an embodiment, the plurality of stages included in the first driver 200 and the plurality of stages included in the fourth driver 500 may be alternately and repeatedly arranged with each other. In an embodiment, the plurality of stages included in the first driver 200 and the plurality of stages included in the fourth driver 500 may be alternately and repeatedly arranged with each other along the second direction DR2, for example. In an embodiment, as illustrated in FIG. 2, the 4-2 stage 520 may be disposed between the 1-1 stage 210 and the 1-3 stage 230, and the 1-3 stage 230 may be disposed between the 4-2 stage 520 and the 4-4 stage 540, for example. The 1-2 stage 220 may be disposed between the 4-1 stage 510 and the 4-3 stage 530, and the 4-3 stage 530 may be disposed between the 1-2 stage 220 and the 1-4 stage 240.

In an embodiment, the plurality of stages included in the second driver 300 and the plurality of stages included in the third driver 400 may be alternately and repeatedly arranged with each other. In an embodiment, the plurality of stages included in the second driver 300 and the plurality of stages included in the third driver 400 may be alternately and repeatedly arranged with each other along the second direction DR2, for example. In an embodiment, as illustrated in FIG. 2, the 3-2 stage 420 may be disposed between the 2-1 stage 310 and the 2-3 stage 330, and the 2-3 stage 330 may be disposed between the 3-2 stage 420 and the 3-4 stage 440, for example. The 2-2 stage 320 may be disposed between the 3-1 stage 410 and the 3-3 stage 430, and the 3-3 stage 430 may be disposed between the 2-2 stage 320 and the 2-4 stage 340.

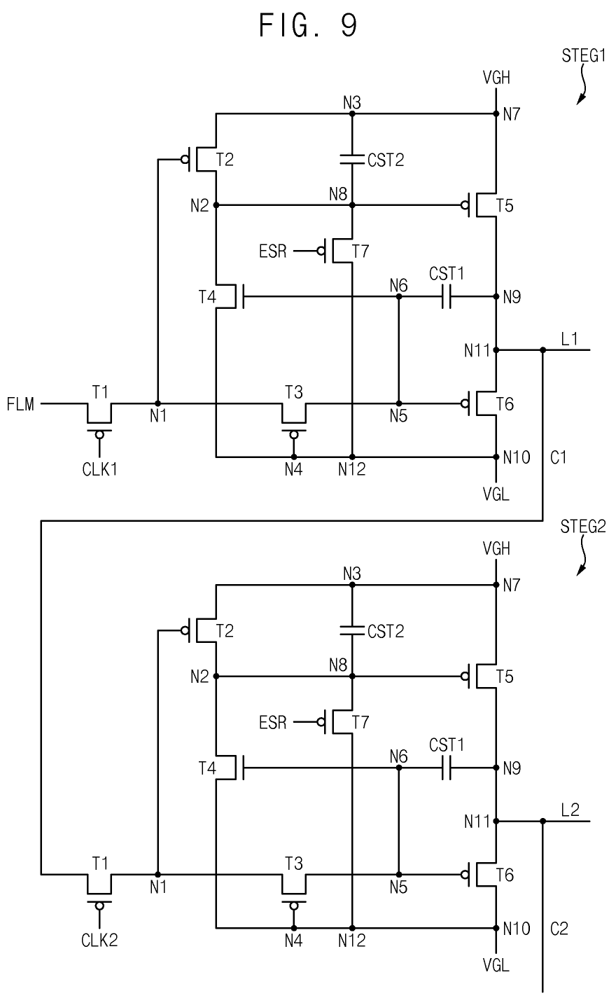

Referring to FIGS. 3, 4, and 5, the 1-1 stage 210 may receive a start signal (e.g., a start signal FLM of FIG. 9) and may provide the 1-1 signal SA1 to the display area DA. In an embodiment, the 1-3 stage 230 may receive the 1-1 signal SA1 from the 1-1 stage 210 and may provide the 1-3 signal SA3 to the display area DA. In an embodiment, the 1-1 stage 210 may provide the 1-1 signal SA1 to the 1-3 stage 230 through a 1-1 transfer line CA1, for example. The 1-3 stage 230 may provide the 1-3 signal SA3 to a next stage through a 1-3 transfer line CA3.

The 1-2 stage 220 may receive a start signal (e.g., a start signal FLM of FIG. 9) and may provide the 1-2 signal SA2 to the display area DA. In an embodiment, the 1-4 stage 240 may receive the 1-2 signal SA2 from the 1-2 stage 220 and may provide the 1-4 signal SA4 to the display area DA. In an embodiment, the 1-2 stage 220 may provide the 1-2 signal SA2 to the 1-4 stage 240 through a 1-2 transfer line CA2, for example. The 1-4 stage 240 may provide the 1-4 signal SA4 to a next stage through a 1-4 transfer line CA4.

In an embodiment, as illustrated in FIG. 3, the 1-1 transfer line CA1 may cross the 4-2 stage 520 in the plan view. In an embodiment, the 1-1 transfer line CA1 may extend in the second direction DR2 and may cross the 4-2 stage 520 in the plan view, for example. In an embodiment, the 1-1 transfer line CA1 may at least partially overlap the 4-2 stage 520 in the plan view. In an embodiment, the 1-1 transfer line CA1 may cross a transistor or a capacitor included in the 4-2 stage 520 in the plan view. In an embodiment, the 1-1 transfer line CA1 may at least partially overlap the transistor or the capacitor included in the 4-2 stage 520 in the plan view, for example.

In embodiments of this disclosure, when the 1-1 transfer line CA1 is disposed to cross the 4-2 stage 520, a separate space for placing the 1-1 transfer line CA1 may not be desired. In an embodiment, by placing the 1-1 transfer line CA1 on the 4-2 stage 520, the 1-1 transfer line CA1 may be disposed using a space in which the 4-2 stage 520 is disposed, for example. Accordingly, dead space of the display device (e.g., the display device DD of FIG. 1) may be reduced. In an embodiment, an area of the non-display area (e.g., the non-display area NDA of FIG. 1) may be reduced, for example.

In an embodiment, the 1-1 transfer line CA1 may cross one stage (e.g., the 4-2 stage 520). However, this disclosure is not necessarily limited thereto, and the 1-1 transfer line CA1 may cross a plurality of stages.

In an embodiment, as illustrated in FIG. 4, the 1-2 transfer line CA2 may cross the 4-3 stage 530 in the plan view. In an embodiment, the 1-2 transfer line CA2 may extend in the second direction DR2 and may cross the 4-3 stage 530 in the plan view, for example. In an embodiment, the 1-2 transfer line CA2 may at least partially overlap the 4-3 stage 530 in the plan view. In an embodiment, the 1-2 transfer line CA2 may cross a transistor or a capacitor included in the 4-3 stage 530 in the plan view. In an embodiment, the 1-2 transfer line CA2 may at least partially overlap the transistor or the capacitor included in the 4-3 stage 530 in the plan view, for example.

In embodiments of this disclosure, when the 1-2 transfer line CA2 is disposed to cross the 4-3 stage 530, a separate space for placing the 1-2 transfer line CA2 may not be desired. In an embodiment, by placing the 1-2 transfer line CA2 on the 4-3 stage 530, the 1-2 transfer line CA2 may be disposed using a space in which the 4-3 stage 530 is disposed, for example. Accordingly, dead space of the display device may be reduced. In an embodiment, an area of the non-display area may be reduced, for example.

In an embodiment, the 1-2 transfer line CA2 may cross one stage (e.g., the 4-3 stage 530). However, this disclosure is not necessarily limited thereto, and the 1-2 transfer line CA2 may cross a plurality of stages.

In an embodiment, as illustrated in FIG. 3, the 1-3 transfer line CA3 may cross the 4-4 stage 540 in the plan view. In an embodiment, the 1-3 transfer line CA3 may extend in the second direction DR2 and may cross the 4-4 stage 540 in the plan view, for example. In an embodiment, the 1-3 transfer line CA3 may at least partially overlap the 4-4 stage 540 in the plan view. In an embodiment, the 1-3 transfer line CA3 may cross a transistor or a capacitor included in the 4-4 stage 540 in the plan view. In an embodiment, the 1-3 transfer line CA3 may at least partially overlap the transistor or the capacitor included in the 4-4 stage 540 in the plan view, for example.

By embodiments of this disclosure, when the 1-3 transfer line CA3 is disposed to cross the 4-4 stage 540, a separate space for placing the 1-3 transfer line CA3 may not be desired. In an embodiment, by placing the 1-3 transfer line CA3 on the 4-4 stage 540, the 1-3 transfer line CA3 may be disposed using a space in which the 4-4 stage 540 is disposed, for example. Accordingly, dead space of the display device may be reduced. In an embodiment, an area of the non-display area may be reduced, for example.

In an embodiment, the 1-3 transfer line CA3 may cross one stage (e.g., the 4-4 stage 540). However, this disclosure is not necessarily limited thereto, and the 1-3 transfer line CA3 may cross a plurality of stages.

In addition, the 1-4 transfer line CA4 may cross a stage included in the fourth driver (e.g., the fourth driver 500 of FIG. 2). In an embodiment, the 1-4 transfer line CA4 may extend in the second direction DR2 and may cross the stage included in the fourth driver, for example.

Referring to FIGS. 3, 4, and 6, the 2-1 stage 310 may receive a start signal (e.g., a start signal FLM of FIG. 9) and may provide the 2-1 signal SB1 to the display area DA. In an embodiment, the 2-3 stage 330 may receive the 2-1 signal SB1 from the 2-1 stage 310 and may provide the 2-3 signal SB3 to the display area DA. In an embodiment, the 2-1 stage 310 may provide the 2-1 signal SB1 to the 2-3 stage 330 through a 2-1 transfer line CB1, for example. The 2-3 stage 330 may provide the 2-3 signal SB3 to a next stage through a 2-3 transfer line CB3.

The 2-2 stage 320 may receive a start signal (e.g., a start signal FLM of FIG. 9) and may provide the 2-2 signal SB2 to the display area DA. In an embodiment, the 2-4 stage 340 may receive the 2-2 signal SB2 from the 2-2 stage 320 and may provide the 2-4 signal SB4 to the display area DA. In an embodiment, the 2-2 stage 320 may provide the 2-2 signal SB2 to the 2-4 stage 340 through a 2-2 transfer line CB2, for example. The 2-4 stage 340 may provide the 2-4 signal SB4 to a next stage through a 2-4 transfer line CB4.

In an embodiment, as illustrated in FIG. 3, the 2-1 transfer line CB1 may cross the 3-2 stage 420 in the plan view. In an embodiment, the 2-1 transfer line CB1 may extend in the second direction DR2 and may cross the 3-2 stage 420 in the plan view, for example. In an embodiment, the 2-1 transfer line CB1 may at least partially overlap the 3-2 stage 420 in the plan view. In an embodiment, the 2-1 transfer line CB1 may cross a transistor or a capacitor included in the 3-2 stage 420 in the plan view. In an embodiment, the 2-1 transfer line CB1 may at least partially overlap the transistor or the capacitor included in the 3-2 stage 420 in the plan view, for example.

In embodiments of this disclosure, when the 2-1 transfer line CB1 is disposed to cross the 3-2 stage 420, a separate space for placing the 2-1 transfer line CB1 may not be desired. In an embodiment, by placing the 2-1 transfer line CB1 on the 3-2 stage 420, the 2-1 transfer line CB1 may be disposed using a space in which the 3-2 stage 420 is disposed, for example. Accordingly, dead space of the display device may be reduced. In an embodiment, an area of the non-display area may be reduced, for example.

In an embodiment, the 2-1 transfer line CB1 may cross one stage (e.g., the 3-2 stage 420). However, this disclosure is not necessarily limited thereto, and the 2-1 transfer line CB1 may cross a plurality of stages.

In an embodiment, as illustrated in FIG. 4, the 2-2 transfer line CB2 may cross the 3-3 stage 430 in the plan view. In an embodiment, the 2-2 transfer line CB2 may extend in the second direction DR2 and may cross the 3-3 stage 430 in the plan view, for example. In an embodiment, the 2-2 transfer line CB2 may at least partially overlap the 3-3 stage 430 in the plan view. In an embodiment, the 2-2 transfer line CB2 may cross a transistor or a capacitor included in the 3-3 stage 430 in the plan view. In an embodiment, the 2-2 transfer line CB2 may at least partially overlap the transistor or the capacitor included in the 3-3 stage 430 in the plan view, for example.

In embodiments of this disclosure, when the 2-2 transfer line CB2 is disposed to cross the 3-3 stage 430, a separate space for placing the 2-2 transfer line CB2 may not be desired. In an embodiment, by placing the 2-2 transfer line CB2 on the 3-3 stage 430, the 2-2 transfer line CB2 may be disposed using a space in which the 3-3 stage 430 is disposed, for example. Accordingly, dead space of the display device may be reduced. In an embodiment, an area of the non-display area may be reduced, for example.

In an embodiment, the 2-2 transfer line CB2 may cross one stage (e.g., the 3-3 stage 430). However, this disclosure is not necessarily limited thereto, and the 2-2 transfer line CB2 may cross a plurality of stages.

In an embodiment, as illustrated in FIG. 3, the 2-3 transfer line CB3 may cross the 3-4 stage 440 in the plan view. In an embodiment, the 2-3 transfer line CB3 may extend in the second direction DR2 and may cross the 3-4 stage 440 in the plan view, for example. In an embodiment, the 2-3 transfer line CB3 may at least partially overlap the 3-4 stage 440 in the plan view. In an embodiment, the 2-3 transfer line CB3 may cross a transistor or a capacitor included in the 3-4 stage 440 in the plan view. In an embodiment, the 2-3 transfer line CB3 may at least partially overlap the transistor or the capacitor included in the 3-4 stage 440 in the plan view, for example.

In embodiments of this disclosure, when the 2-3 transfer line CB3 is disposed to cross the 3-4 stage 440, a separate space for placing the 2-3 transfer line CB3 may not be desired. In an embodiment, by placing the 2-3 transfer line CB3 on the 3-4 stage 440, the 2-3 transfer line CB3 may be disposed using a space in which the 3-4 stage 440 is disposed, for example. Accordingly, dead space of the display device may be reduced. In an embodiment, an area of the non-display area may be reduced, for example.

In an embodiment, the 2-3 transfer line CB3 may cross one stage (e.g., the 3-4 stage 440). However, this disclosure is not necessarily limited thereto, and the 2-3 transfer line CB3 may cross a plurality of stages.

In addition, the 2-4 transfer line CB4 may cross a stage included in the third driver (e.g., the third driver 400 of FIG. 2). In an embodiment, the 2-4 transfer line CB4 may extend in the second direction DR2 and may cross the stage included in the third driver, for example.

Referring to FIGS. 3, 4, and 7, the 3-1 stage 410 may receive a start signal (e.g., a start signal FLM of FIG. 9) and may provide the 3-1 signal SC1 to the display area DA. In an embodiment, the 3-3 stage 430 may receive the 3-1 signal SC1 from the 3-1 stage 410 and may provide the 3-3 signal SC3 to the display area DA. In an embodiment, the 3-1 stage 410 may provide the 3-1 signal SC1 to the 3-3 stage 430 through a 3-1 transfer line CC1, for example. The 3-3 stage 430 may provide the 3-3 signal SC3 to a next stage through a 3-3 transfer line CC3.

The 3-2 stage 420 may receive a start signal (e.g., a start signal FLM of FIG. 9) and may provide the 3-2 signal SC2 to the display area DA. In an embodiment, the 3-4 stage 440 may receive the 3-2 signal SC2 from the 3-2 stage 420 and may provide the 3-4 signal SC4 to the display area DA. In an embodiment, the 3-2 stage 420 may provide the 3-2 signal SC2 to the 3-4 stage 440 through a 3-2 transfer line CC2, for example. The 3-4 stage 440 may provide the 3-4 signal SC4 to a next stage through a 3-4 transfer line CC4.

In an embodiment, as illustrated in FIG. 4, the 3-1 transfer line CC1 may cross the 2-2 stage 320 in the plan view. In an embodiment, the 3-1 transfer line CC1 may extend in the second direction DR2 and may cross the 2-2 stage 320 in the plan view, for example. In an embodiment, the 3-1 transfer line CC1 may at least partially overlap the 2-2 stage 320 in the plan view. In an embodiment, the 3-1 transfer line CC1 may cross a transistor or a capacitor included in the 2-2 stage 320 in the plan view. In an embodiment, the 3-1 transfer line CC1 may at least partially overlap the transistor or the capacitor included in the 2-2 stage 320 in the plan view, for example.

In embodiments of this disclosure, when the 3-1 transfer line CC1 is disposed to cross the 2-2 stage 320, a separate space for placing the 3-1 transfer line CC1 may not be desired. In an embodiment, by placing the 3-1 transfer line CC1 on the 2-2 stage 320, the 3-1 transfer line CC1 may be disposed using a space in which the 2-2 stage 320 is disposed, for example. Accordingly, dead space of the display device may be reduced. In an embodiment, an area of the non-display area may be reduced, for example.

In an embodiment, the 3-1 transfer line CC1 may cross one stage (e.g., the 2-2 stage 320). However, this disclosure is not necessarily limited thereto, and the 3-1 transfer line CC1 may cross a plurality of stages.

In an embodiment, as illustrated in FIG. 3, the 3-2 transfer line CC2 may cross the 2-3 stage 330 in the plan view. In an embodiment, the 3-2 transfer line CC2 may extend in the second direction DR2 and may cross the 2-3 stage 330 in the plan view, for example. In an embodiment, the 3-2 transfer line CC2 may at least partially overlap the 2-3 stage 330 in the plan view. In an embodiment, the 3-2 transfer line CC2 may cross a transistor or a capacitor included in the 2-3 stage 330 in the plan view. In an embodiment, the 3-2 transfer line CC2 may at least partially overlap the transistor or the capacitor included in the 2-3 stage 330 in the plan view, for example.

In embodiments of this disclosure, when the 3-2 transfer line CC2 is disposed to cross the 2-3 stage 330, a separate space for placing the 3-2 transfer line CC2 may not be desired. In an embodiment, by placing the 3-2 transfer line CC2 on the 2-3 stage 330, the 3-2 transfer line CC2 may be disposed using a space in which the 2-3 stage 330 is disposed, for example. Accordingly, dead space of the display device may be reduced. In an embodiment, an area of the non-display area may be reduced, for example.

In an embodiment, the 3-2 transfer line CC2 may cross one stage (e.g., the 2-3 stage 330). However, this disclosure is not necessarily limited thereto, and the 3-2 transfer line CC2 may cross a plurality of stages.

In an embodiment, as illustrated in FIG. 4, the 3-3 transfer line CC3 may cross the 2-4 stage 340 in the plan view. In an embodiment, the 3-3 transfer line CC3 may extend in the second direction DR2 and may cross the 2-4 stage 340 in the plan view, for example. In an embodiment, the 3-3 transfer line CC3 may at least partially overlap the 2-4 stage 340 in the plan view. In an embodiment, the 3-3 transfer line CC3 may cross a transistor or a capacitor included in the 2-4 stage 340 in the plan view. In an embodiment, the 3-3 transfer line CC3 may at least partially overlap the transistor or the capacitor included in the 2-4 stage 340 in the plan view, for example.

In embodiments of this disclosure, when the 3-3 transfer line CC3 is disposed to cross the 2-4 stage 340, a separate space for placing the 3-3 transfer line CC3 may not be desired. In an embodiment, by placing the 3-3 transfer line CC3 on the 2-4 stage 340, the 3-3 transfer line CC3 may be disposed using a space in which the 2-4 stage 340 is disposed, for example. Accordingly, dead space of the display device may be reduced. In an embodiment, an area of the non-display area may be reduced, for example.

In an embodiment, the 3-3 transfer line CC3 may cross one stage (e.g., the 2-4 stage 340). However, this disclosure is not necessarily limited thereto, and the 3-3 transfer line CC3 may cross a plurality of stages.

In addition, the 3-4 transfer line CC4 may cross a stage included in the second driver (e.g., the second driver 300 of FIG. 2). In an embodiment, the 3-4 transfer line CC4 may extend in the second direction DR2 and may cross the stage included in the second driver, for example.

Referring to FIGS. 3, 4, and 8, the 4-1 stage 510 may receive a start signal (e.g., a start signal FLM of FIG. 9) and may provide the 4-1 signal SD1 to the display area DA. In an embodiment, the 4-3 stage 530 may receive the 4-1 signal SD1 from the 4-1 stage 510 and may provide the 4-3 signal SD3 to the display area DA. In an embodiment, the 4-1 stage 510 may provide the 4-1 signal SD1 to the 4-3 stage 530 through a 4-1 transfer line CD1, for example. The 4-3 stage 530 may provide the 4-3 signal SD3 to a next stage through a 4-3 transfer line CD3.

The 4-2 stage 520 may receive a start signal (e.g., a start signal FLM of FIG. 9) and may provide the 4-2 signal SD2 to the display area DA. In an embodiment, the 4-4 stage 540 may receive the 4-2 signal SD2 from the 4-2 stage 520 and may provide the 4-4 signal SD4 to the display area DA. In an embodiment, the 4-2 stage 520 may provide the 4-2 signal SD2 to the 4-4 stage 540 through a 4-2 transfer line CD2. The 4-4 stage 540 may provide the 4-4 signal SD4 to a next stage through a 4-4 transfer line CD4, for example.

In an embodiment, as illustrated in FIG. 4, the 4-1 transfer line CD1 may cross the 1-2 stage 220 in the plan view. In an embodiment, the 4-1 transfer line CD1 may extend in the second direction DR2 and may cross the 1-2 stage 220 in the plan view, for example. In an embodiment, the 4-1 transfer line CD1 may at least partially overlap the 1-2 stage 220 in the plan view. In an embodiment, the 4-1 transfer line CD1 may cross a transistor or a capacitor included in the 1-2 stage 220 in the plan view. In an embodiment, the 4-1 transfer line CD1 may at least partially overlap the transistor or the capacitor included in the 1-2 stage 220 in the plan view, for example.

In embodiments of this disclosure, when the 4-1 transfer line CD1 is disposed to cross the 1-2 stage 220, a separate space for placing the 4-1 transfer line CD1 may not be desired. In an embodiment, by placing the 4-1 transfer line CD1 on the 1-2 stage 220, the 4-1 transfer line CD1 may be disposed using a space in which the 1-2 stage 220 is disposed, for example. Accordingly, dead space of the display device may be reduced. In an embodiment, an area of the non-display area may be reduced, for example.

In an embodiment, the 4-1 transfer line CD1 may cross one stage (e.g., the 1-2 stage 220). However, this disclosure is not necessarily limited thereto, and the 4-1 transfer line CD1 may cross a plurality of stages.

In an embodiment, as illustrated in FIG. 3, the 4-2 transfer line CD2 may cross the 1-3 stage 230 in the plan view. In an embodiment, the 4-2 transfer line CD2 may extend in the second direction DR2 and may cross the 1-3 stage 230 in the plan view, for example. In an embodiment, the 4-2 transfer line CD2 may at least partially overlap the 1-3 stage 230 in the plan view. In an embodiment, the 4-2 transfer line CD2 may cross a transistor or a capacitor included in the 1-3 stage 230 in the plan view. In an embodiment, the 4-2 transfer line CD2 may at least partially overlap the transistor or the capacitor included in the 1-3 stage 230 in the plan view, for example.

In embodiments of this disclosure, when the 4-2 transfer line CD2 is disposed to cross the 1-3 stage 230, a separate space for placing the 4-2 transfer line CD2 may not be desired. In an embodiment, by placing the 4-2 transfer line CD2 on the 1-3 stage 230, the 4-2 transfer line CD2 may be disposed using a space in which the 1-3 stage 230 is disposed, for example. Accordingly, dead space of the display device may be reduced. In an embodiment, an area of the non-display area may be reduced, for example.

In an embodiment, the 4-2 transfer line CD2 may cross one stage (e.g., the 1-3 stage 230). However, this disclosure is not necessarily limited thereto, and the 4-2 transfer line CD2 may cross a plurality of stages.

In an embodiment, as illustrated in FIG. 4, the 4-3 transfer line CD3 may cross the 1-4 stage 240 in the plan view. In an embodiment, the 4-3 transfer line CD3 may extend in the second direction DR2 and may cross the 1-4 stage 240 in the plan view, for example. In an embodiment, the 4-3 transfer line CD3 may at least partially overlap the 1-4 stage 240 in the plan view. In an embodiment, the 4-3 transfer line CD3 may cross a transistor or a capacitor included in the 1-4 stage 240 in the plan view. In an embodiment, the 4-3 transfer line CD3 may at least partially overlap the transistor or the capacitor included in the 1-4 stage 240 in the plan view, for example.

In embodiments of this disclosure, when the 4-3 transfer line CD3 is disposed to cross the 1-4 stage 240, a separate space for placing the 4-3 transfer line CD3 may not be desired. In an embodiment, by placing the 4-3 transfer line CD3 on the 1-4 stage 240, the 4-3 transfer line CD3 may be disposed using a space in which the 1-4 stage 240 is disposed, for example. Accordingly, dead space of the display device may be reduced. In an embodiment, an area of the non-display area may be reduced, for example.

In an embodiment, the 4-3 transfer line CD3 may cross one stage (e.g., the 1-4 stage 240). However, this disclosure is not necessarily limited thereto, and the 4-3 transfer line CD3 may cross a plurality of stages.

In addition, the 4-4 transfer line CD4 may cross a stage included in the first driver (e.g., the first driver 200 of FIG. 2). In an embodiment, the 4-4 transfer line CD4 may extend in the second direction DR2 and may cross a stage included in the fourth driver, for example.

FIG. 9 is a circuit diagram illustrating the drivers included in the display device of FIG. 2.

Referring to FIGS. 2 and 9, the first driver 200, the second driver 300, the third driver 400, and the fourth driver 500 may each include a first stage STEG1 and a second stage STEG2. In an embodiment, each of the 1-1 stage 210, the 2-1 stage 310, the 3-1 stage 410, the 4-1 stage 510, the 4-2 stage 520, the 3-2 stage 420, the 2-2 stage 320, and the 1-2 stage 220 may correspond to the first stage STEG1, and each of the 1-3 stage 230, the 2-3 stage 330, the 3-3 stage 430, the 4-3 stage 530, the 4-4 stage 540, the 3-4 stage 440, the 2-4 stage 340, and the 1-4 stage 240 may correspond to the second stage STEG2, for example, but this disclosure is not necessarily limited thereto.

In an embodiment, each of the first stage STEG1 and the second stage STEG2 may include a first transistor T1, a second transistor T2, a third transistor T3, a fourth transistor T4, a fifth transistor T5, a sixth transistor T6, a seventh transistor T7, a first capacitor CST1, and a second capacitor CST2.

A first electrode of the first transistor T1 included in the first stage STEG1 may receive a start signal FLM, and a first electrode of the first transistor T1 included in the second stage STEG2 may be connected to a first transfer line C1. In addition, a second transfer line C2 may be connected to a first transistor included in a third stage (not illustrated).

In an embodiment, each of the 1-1 transfer line (e.g., the 1-1 transfer line CA1 of FIG. 3), the 2-1 transfer line (e.g., the 2-1 transfer line CB1 of FIG. 3), the 4-2 transfer line (e.g., the 4-2 transfer line CD2 of FIG. 3), the 3-2 transfer line (e.g., the 3-2 transfer line CC2 of FIG. 3), the 3-1 transfer line (e.g., the 3-1 transfer line CC1 of FIG. 4), the 4-1 transfer line (e.g., the 4-1 transfer line CD1 of FIG. 4), the 2-2 transfer line (e.g., the 2-2 transfer line CB2 of FIG. 4), and the 1-2 transfer line (e.g., the 1-2 transfer line CA2 of FIG. 4) may correspond to the first transfer line C1, but this disclosure is not necessarily limited thereto.

In an embodiment, each of the 1-3 transfer line (e.g., the 1-3 transfer line CA3 of FIG. 3), the 2-3 transfer line (e.g., the 2-3 transfer line CB3 of FIG. 3), the 4-4 transfer line (e.g., the 4-4 transfer line CD4 of FIG. 3), the 3-4 transfer line (e.g., the 3-4 transfer line CC4 of FIG. 3), the 3-3 transfer line (e.g., the 3-3 transfer line CC3 of FIG. 4), the 4-3 transfer line (e.g., the 4-3 transfer line CD3 of FIG. 4), the 2-4 transfer line (e.g., the 2-4 transfer line CB4 of FIG. 4), and the 1-4 transfer line (e.g., the 1-4 transfer line CA4 of FIG. 4) may correspond to the second transfer line C2, but this disclosure is not necessarily limited thereto.

The first stage STEG1 may output a signal to the display area DA through a first output line L1. The second stage STEG2 may output a signal to the display area DA through a second output line L2.

In an embodiment, each of the 1-1 output line LA1, the 2-1 output line LB1, the 3-1 output line LC1, the 4-1 output line LD1, the 4-2 output line LD2, the 3-2 output line LC2, the 2-2 output line LB2, and the 1-2 output line LA2 may correspond to the first output line L1, but this disclosure is not necessarily limited thereto.

In an embodiment, each of the 1-3 output line LA3, the 2-3 output line LB3, the 3-3 output line LC3, the 4-3 output line LD3, the 4-4 output line LD4, the 3-4 output line LC4, the 2-4 output line LB4, and the 1-4 output line LA4 may correspond to the second output line L2, but this disclosure is not necessarily limited thereto.

The first stage STEG1 and the second stage STEG2 may have substantially a same structure. Hereinafter, a structure of the first stage STEG1 will be described.

In an embodiment, the first transistor T1, the second transistor T2, the third transistor T3, the fifth transistor T5, the sixth transistor T6, and the seventh transistor T7 may each be a p-channel metal-oxide-semiconductor (“PMOS”) transistor, and the fourth transistor T4 may be an n-channel metal-oxide-semiconductor (“NMOS”) transistor, but this disclosure is not necessarily limited thereto.

In an embodiment, the first transistor T1 may include a first electrode to which the start signal FLM is applied, a gate electrode that receives a first clock signal CLK1, and a second electrode connected to a first node N1. The gate electrode of the first transistor T1 included in the second stage STEG2 may receive a second clock signal CLK2.

The second transistor T2 may include a first electrode connected to a second node N2, a gate electrode connected to the first node N1, and a second electrode connected to a third node N3.

The third transistor T3 may include a first electrode connected to the first node N1, a gate electrode connected to a fourth node N4, and a second electrode connected to a fifth node N5.

The fourth transistor T4 may include a first electrode connected to the second node N2, a gate electrode connected to a sixth node N6, and a second electrode connected to the fourth node N4.

The fifth transistor T5 may include a first electrode connected to a seventh node N7, a gate electrode connected to an eighth node N8, and a second electrode connected to a ninth node N9. The first electrode of the fifth transistor T5 may receive a first power voltage VGH through the seventh node N7.

The sixth transistor T6 may include a first electrode connected to a tenth node N10, a gate electrode connected to the fifth node N5, and a second electrode connected to an eleventh node N11. The first electrode of the sixth transistor T6 may receive a second power voltage VGL through the tenth node N10. In an embodiment, voltage level of the first power voltage VGH may be higher than voltage level of the second power voltage VGL, but this disclosure is not necessarily limited thereto.

The seventh transistor T7 may include a first electrode connected to a twelfth node N12, a gate electrode that receives a blocking signal ESR, and a second electrode connected to the eighth node N8.

The first capacitor CST1 may include a first electrode connected to the sixth node N6 and a second electrode connected to the ninth node N9. The second capacitor CST2 may include a first electrode connected to the eighth node N8 and a second electrode connected to the third node N3.

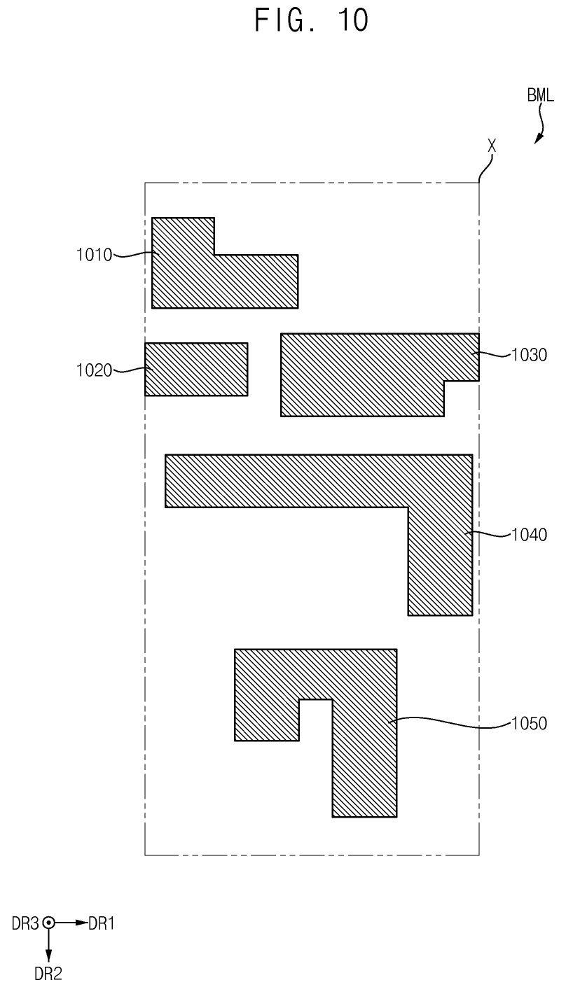

FIGS. 10, 11, 12, 13, 14, 15, 16, 17, 18, 19, 20, and 21, are plan views illustrating a partial area of the display device of FIG. 1. Specifically, FIGS. 10, 11, 12, 13, 14, 15, 16, 17, 18, 19, 20, and 21, are plan views illustrating an X area of FIG. 3.

Referring to FIG. 10, the display device (e.g., the display device DD of FIG. 1) may include a bottom metal layer BML. In an embodiment, the 4-2 stage (e.g., the 4-2 stage 520 of FIG. 3) may include the bottom metal layer BML, for example. The bottom metal layer BML may include a first bottom metal pattern 1010, a second bottom metal pattern 1020, a third bottom metal pattern 1030, a fourth bottom metal pattern 1040, and a fifth bottom metal pattern 1050. The first bottom metal pattern 1010, the second bottom metal pattern 1020, the third bottom metal pattern 1030, the fourth bottom metal pattern 1040, and the fifth bottom metal pattern 1050 may be spaced apart from each other in the plan view.

The bottom metal layer BML may include a metal, an alloy, a metal nitride, a conductive metal oxide, a transparent conductive material, and/or the like. In embodiments, the metal may include silver (Ag), molybdenum (Mo), aluminum (Al), tungsten (W), copper (Cu), nickel (Ni), chromium (Cr), titanium (Ti), tantalum (Ta), platinum (Pt), scandium (Sc), and/or the like. These materials may be used alone or in any combinations with each other. In embodiments, the conductive metal oxide may include Indium tin oxide, indium zinc oxide, and/or the like. These materials may be used alone or in any combinations with each other. In addition, embodiments of the metal nitride may include aluminum nitride (AlNₓ), tungsten nitride (WNₓ), chromium nitride (CrNₓ), and/or the like. These materials may be used alone or in any combinations with each other.

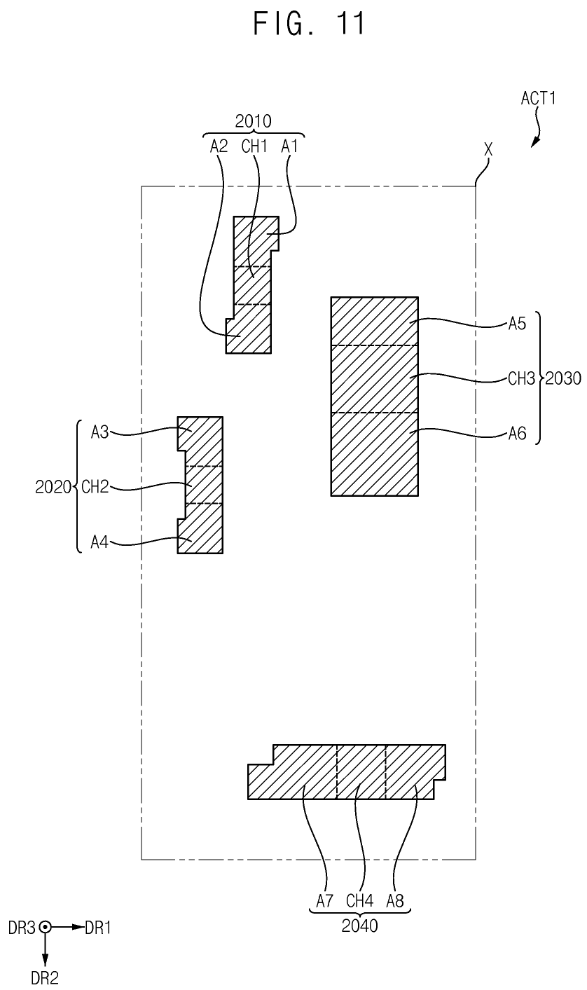

Referring to FIG. 11, the display device may further include a first active layer ACT1. In an embodiment, the 4-2 stage may further include the first active layer ACT1. The first active layer ACT1 may be disposed on the bottom metal layer (e.g., the bottom metal layer BML of FIG. 10), for example. The first active layer ACT1 may include a first active pattern 2010, a second active pattern 2020, a third active pattern 2030, and a fourth active pattern 2040. The first active pattern 2010, the second active pattern 2020, the third active pattern 2030, and the fourth active pattern 2040 may be spaced apart from each other in the plan view.

The first active pattern 2010 may include a first area A1, a first channel area CH1, and a second area A2. The first channel area CH1 may be disposed between the first area A1 and the second area A2. The first area A1 and the second area A2 may be spaced apart from each other in the plan view.

The second active pattern 2020 may include a third area A3, a second channel area CH2, and a fourth area A4. The second channel area CH2 may be disposed between the third area A3 and the fourth area A4. The third area A3 and the fourth area A4 may be spaced apart from each other in the plan view.

The third active pattern 2030 may include a fifth area A5, a third channel area CH3, and a sixth area A6. The third channel area CH3 may be disposed between the fifth area A5 and the sixth area A6. The fifth area A5 and the sixth area A6 may be spaced apart from each other in the plan view.

The fourth active pattern 2040 may include a seventh area A7, a fourth channel area CH4, and an eighth area A8. The fourth channel area CH4 may be disposed between the seventh area A7 and the eighth area A8. The seventh area A7 and the eighth area A8 may be spaced apart from each other in the plan view.

In an embodiment, the first active layer ACT1 may include amorphous silicon, polysilicon, and/or the like. These materials may be used alone or in any combinations with each other, but this disclosure is not necessarily limited thereto, and in another embodiment, the first active layer ACT1 may include a metal oxide semiconductor.

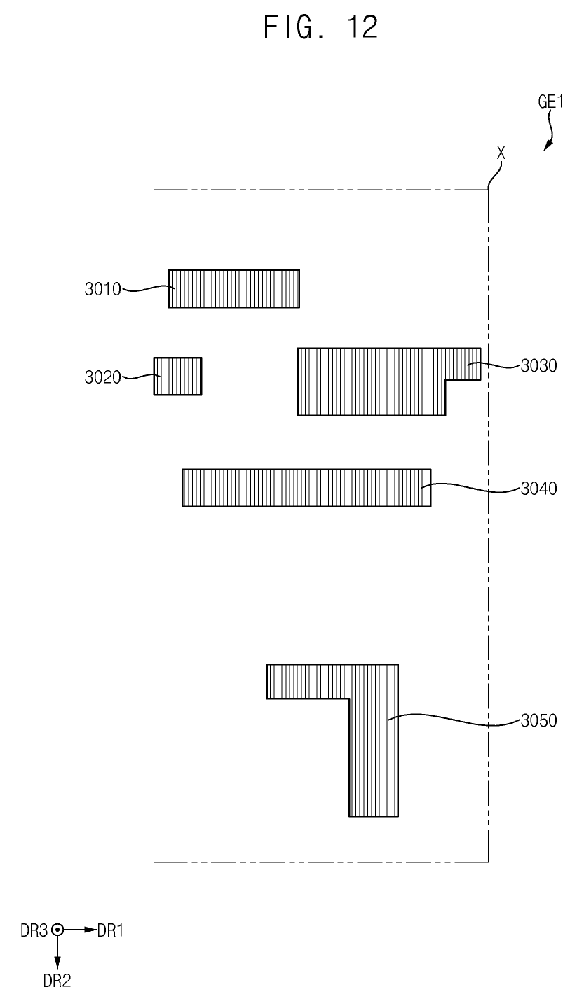

Referring to FIG. 12, the display device may further include a first gate layer GE1. In an embodiment, the 4-2 stage may further include the first gate layer GE1. The first gate layer GE1 may be disposed on the first active layer (e.g., the first active layer ACT1 of FIG. 11), for example. The first gate layer GE1 may include a first gate pattern 3010, a second gate pattern 3020, a third gate pattern 3030, a fourth gate pattern 3040, and a fifth gate pattern 3050. The first gate pattern 3010, the second gate pattern 3020, the third gate pattern 3030, the fourth gate pattern 3040, and the fifth gate pattern 3050 may be spaced apart from each other in the plan view.

The first gate layer GE1 may include a metal, an alloy, a metal nitride, a conductive metal oxide, a transparent conductive material, and/or the like. In embodiments, the metal may include silver (Ag), molybdenum (Mo), aluminum (Al), tungsten (W), copper (Cu), nickel (Ni), chromium (Cr), titanium (Ti), tantalum (Ta), platinum (Pt), scandium (Sc), and/or the like. These materials may be used alone or in any combinations with each other. In embodiments, the conductive metal oxide may include Indium tin oxide, indium zinc oxide, and/or the like. These materials may be used alone or in any combinations with each other. In addition, embodiments of the metal nitride may include aluminum nitride (AlNₓ), tungsten nitride (WNₓ), chromium nitride (CrNₓ), and/or the like. These materials may be used alone or in any combinations with each other.

Referring to FIGS. 11, 12, and 13, the first transistor T1 may include a portion of the third active pattern 2030 and a portion of the third gate pattern 3030. In an embodiment, the first transistor T1 may include at least a portion of the fifth area A5, at least a portion of the sixth area A6, the third channel area CH3, and a portion of the third gate pattern 3030 overlapping the third channel area CH3 in the plan view, for example. In an embodiment, the portion of the third gate pattern 3030 overlapping the third channel area CH3 in the plan view may be also referred to as a gate electrode of the first transistor T1, for example.

The second transistor T2 may include a portion of the second active pattern 2020 and a portion of the fourth gate pattern 3040. In an embodiment, the second transistor T2 may include at least a portion of the third area A3, at least a portion of the fourth area A4, the second channel area CH2, and a portion of the fourth gate pattern 3040 overlapping the second channel area CH2 in the plan view, for example. In an embodiment, the portion of the fourth gate pattern 3040 overlapping the second channel area CH2 in the plan view may be also referred to as a gate electrode of the second transistor T2, for example.

The third transistor T3 may include a portion of the fourth active pattern 2040 and a portion of the fifth gate pattern 3050. In an embodiment, the third transistor T3 may include a portion of the seventh area A7, a portion of the eighth area A8, the fourth channel area CH4, and a portion of the fifth gate pattern 3050 overlapping the fourth channel area CH4 in the plan view, for example. In an embodiment, the portion of the fifth gate pattern 3050 overlapping the fourth channel area CH4 in the plan view may be also referred to as a gate electrode of the third transistor T3, for example.

The seventh transistor T7 may include a portion of the first active pattern 2010 and a portion of the first gate pattern 3010. In an embodiment, the seventh transistor T7 may include a portion of the first area A1, a portion of the second area A2, the first channel area CH1, and a portion of the first gate pattern 3010 overlapping the first channel area CH1 in the plan view, for example. In an embodiment, the portion of the first gate pattern 3010 overlapping the first channel area CH1 in the plan view may be also referred to as a gate electrode of the seventh transistor T7, for example.

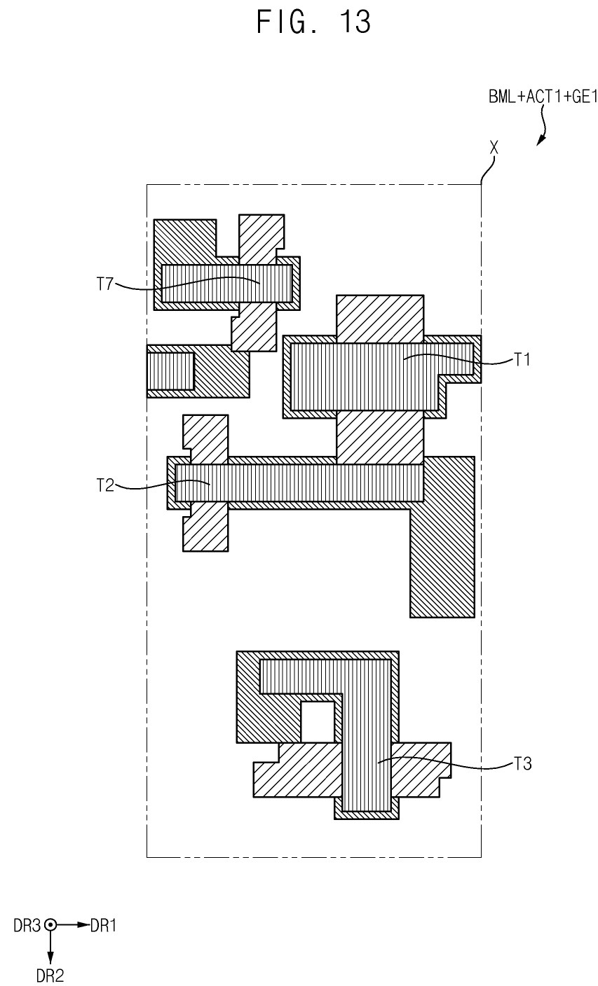

In an embodiment, the first transistor T1 of FIG. 13 may correspond to the first transistor T1 of FIG. 9, the second transistor T2 of FIG. 13 may correspond to the second transistor T2 of FIG. 9, the third transistor T3 of FIG. 13 may correspond to the third transistor T3 of FIG. 9, and the seventh transistor T7 of FIG. 13 may correspond to the seventh transistor T7 of FIG. 9, but this disclosure is not necessarily limited thereto.

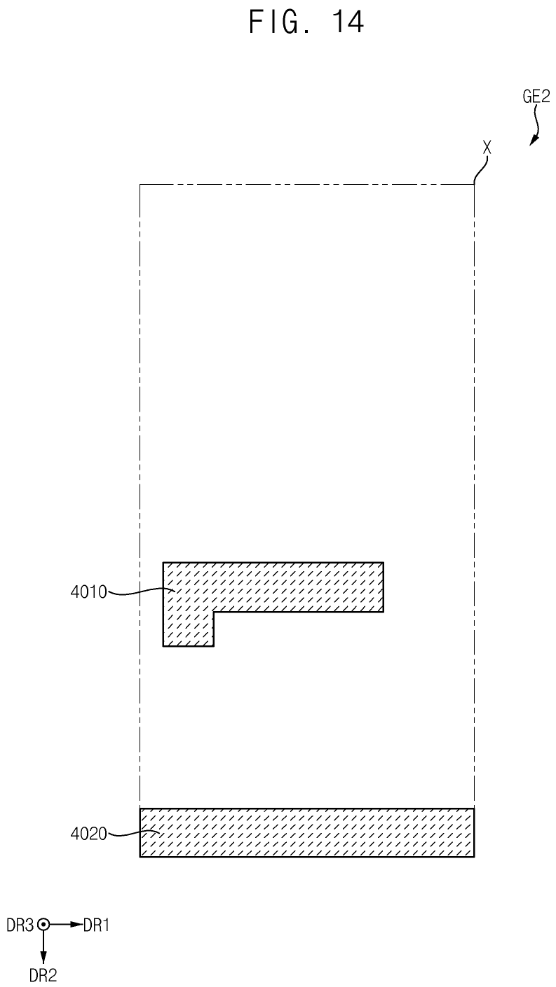

Referring to FIG. 14, the display device may further include a second gate layer GE2. In an embodiment, the 4-2 stage may further include the second gate layer GE2, for example. The second gate layer GE2 may be disposed on the first gate layer (e.g., the first gate layer GE1 of FIG. 13). The second gate layer GE2 may include a sixth gate pattern 4010 and a seventh gate pattern 4020. The sixth gate pattern 4010 and the seventh gate pattern 4020 may be spaced apart from each other in the plan view.

The second gate electrode GE2 may include a metal, an alloy, a metal nitride, a conductive metal oxide, a transparent conductive material, and/or the like. In embodiments, the metal may include silver (Ag), molybdenum (Mo), aluminum (Al), tungsten (W), copper (Cu), nickel (“Ni”), chromium (“Cr”), titanium (“Ti”), tantalum (“Ta”), platinum (“Pt”), scandium (“Sc”), and/or the like. These materials may be used alone or in any combinations with each other. In embodiments, the conductive metal oxide may include Indium tin oxide, indium zinc oxide, and/or the like. These materials may be used alone or in any combinations with each other. In addition, embodiments of the metal nitride may include aluminum nitride (AlNₓ), tungsten nitride (WNₓ), chromium nitride (CrNₓ), and/or the like. These materials may be used alone or in any combinations with each other.

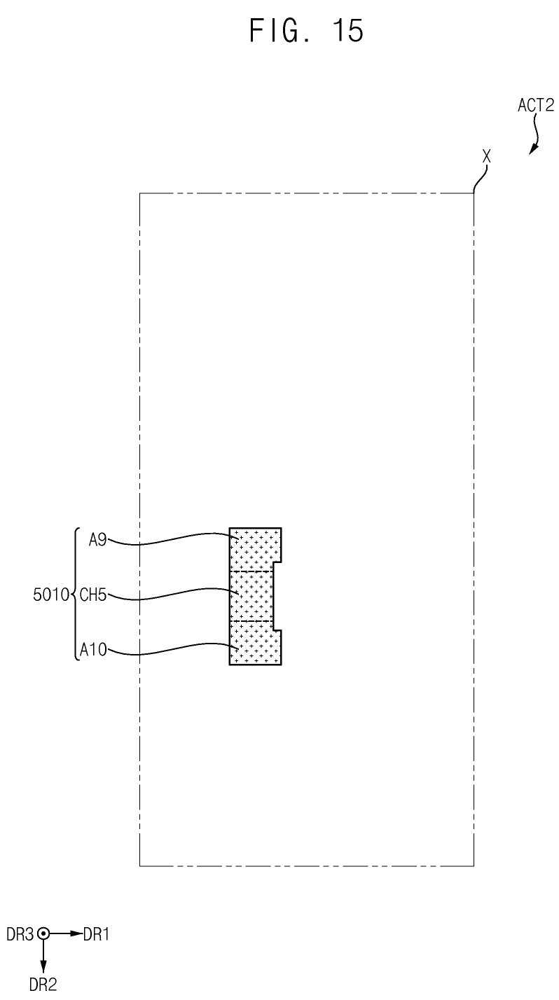

Referring to FIG. 15, the display device may further include a second active layer ACT2. In an embodiment, the 4-2 stage may further include the second active layer ACT2, for example. The second active layer ACT2 may be disposed on the second gate layer (e.g., the second gate layer GE2 of FIG. 14). The second active layer ACT2 may include a fifth active pattern 5010.

The fifth active pattern 5010 may include the ninth area A9, the tenth area A10, and the fifth channel area CH5. The fifth channel area CH5 may be disposed between the ninth area A9 and the tenth area A10. The ninth area A9 and the tenth area A10 may be spaced apart from each other in the plan view.

In an embodiment, the second active layer ACT2 may include a metal oxide semiconductor. The metal oxide semiconductor may include a binary compound (ABₓ), a ternary compound (ABₓC_{y}), a quaternary compound (ABₓC_{y}D_{z}), and/or the like including indium (In), zinc (Zn), gallium (Ga), tin (Sn), titanium (Ti), aluminum (Al), hafnium (Hf), zirconium (Zr), magnesium (Mg), and/or the like. These materials may be used alone or in any combinations with each other. In an embodiment, the metal oxide semiconductor may include zinc oxide (ZnOₓ), gallium oxide (GaOₓ), tin oxide (SnOₓ), indium oxide (InOₓ), indium gallium oxide (“IGO”), indium zinc oxide (“IZO”), indium tin oxide (“ITO”), indium zinc tin oxide (“IZTO”), and indium gallium zinc oxide (“IGZO”), for example. These materials may be used alone or in any combinations with each other. However, this disclosure is not necessarily limited thereto, and in another embodiment, the second active layer ACT2 may include amorphous silicon, polysilicon, and/or the like.

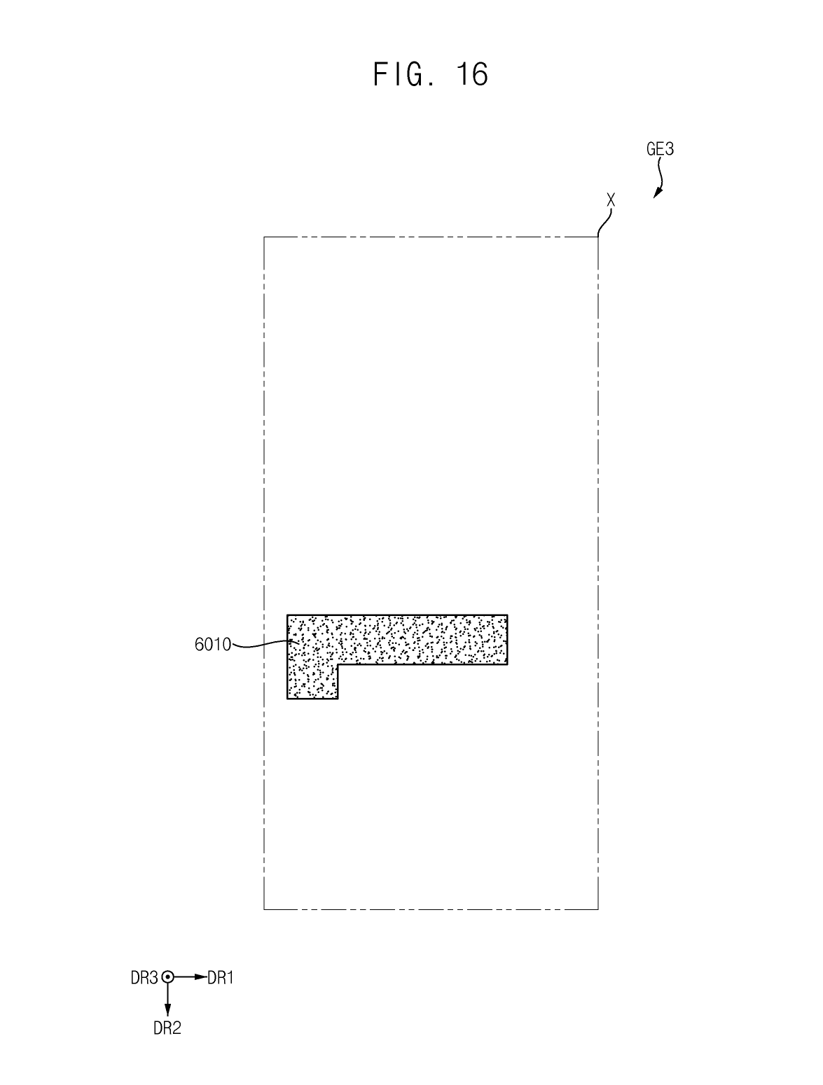

Referring to FIG. 16, the display device may further include a third gate layer GE3. In an embodiment, the 4-2 stage may further include the third gate layer GE3, for example. The third gate layer GE3 may be disposed on the second active layer (e.g., the second active layer ACT2 of FIG. 15.). The third gate layer GE3 may include an eighth gate pattern 6010.

The third gate layer GE3 may include a metal, an alloy, a metal nitride, a conductive metal oxide, a transparent conductive material, and/or the like. In embodiments, the metal may include silver (Ag), molybdenum (Mo), aluminum (Al), tungsten (W), copper (Cu), nickel (Ni), chromium (Cr), titanium (Ti), tantalum (Ta), platinum (Pt), scandium (Sc), and/or the like. These materials may be used alone or in any combinations with each other. In embodiments, the conductive metal oxide may include Indium tin oxide, indium zinc oxide, and/or the like. These materials may be used alone or in any combinations with each other. In addition, embodiments of the metal nitride may include aluminum nitride (AlNₓ), tungsten nitride (WNₓ), chromium nitride (CrNₓ), and/or the like. These materials may be used alone or in any combinations with each other.

Referring to FIGS. 15, 16 and 17, the fourth transistor T4 may include a portion of the fifth active pattern 5010 and a portion of the eighth gate pattern 6010. In an embodiment, the fourth transistor T4 may include at least a portion of the ninth area A9, at least a portion of the tenth area A10, the fifth channel area CH5, and a portion of the eighth gate pattern 6010 overlapping the fifth channel area CH5 in the plan view, for example. In an embodiment, the portion of the eighth gate pattern 6010 overlapping the fifth channel area CH5 in the plan view may be also referred to as a gate electrode of the fourth transistor T4, for example.

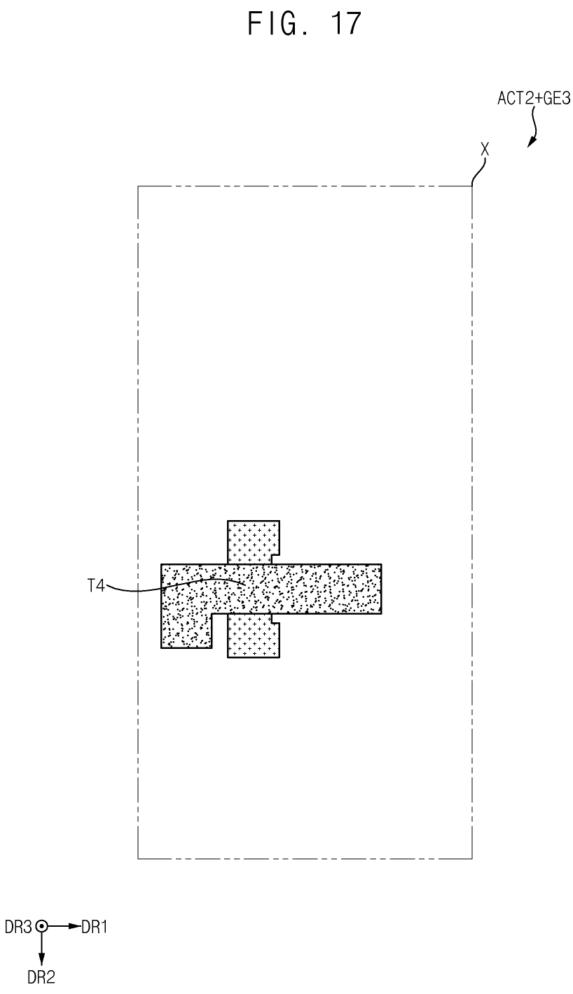

In an embodiment, the fourth transistor T4 of FIG. 17 may correspond to the fourth transistor T4 of FIG. 9, but this disclosure is not necessarily limited thereto.

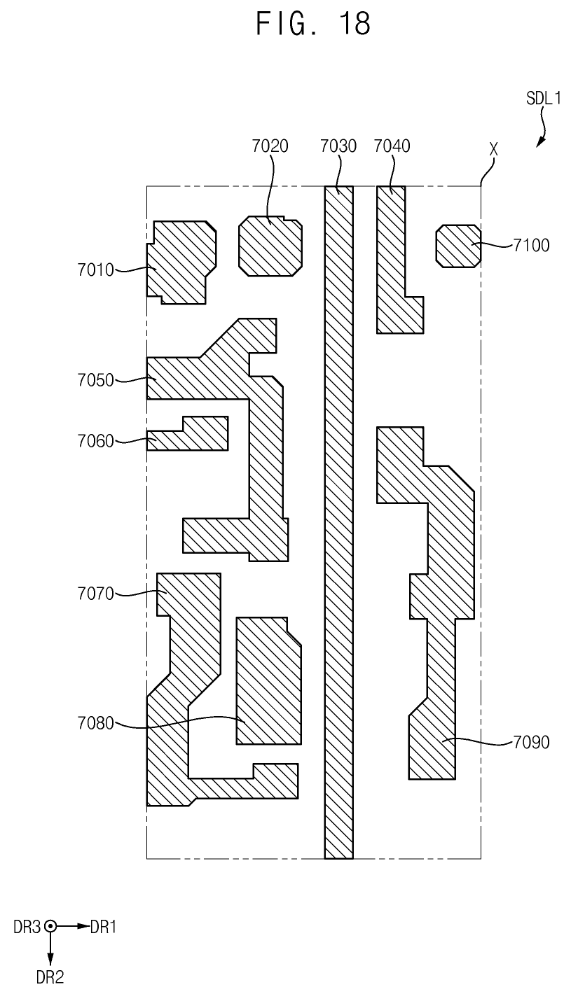

Referring to FIG. 18, the display device may further include a first electrode layer SDL1. In an embodiment, the 4-2 stage may further include the first electrode layer SDL1, for example. The first electrode layer SDL1 may be disposed on the third gate layer (e.g., the third gate layer GE3 of FIG. 17). The first electrode layer SDL1 may include a first electrode pattern 7010, a second electrode pattern 7020, a third electrode pattern 7030, a fourth electrode pattern 7040, a fifth electrode pattern 7050, a sixth electrode pattern 7060, a seventh electrode pattern 7070, an eighth electrode pattern 7080, a ninth electrode pattern 7090, and a tenth electrode pattern 7100. The first electrode pattern 7010, the second electrode pattern 7020, the third electrode pattern 7030, the fourth electrode pattern 7040, the fifth electrode pattern 7050, the sixth electrode pattern 7060, the seventh electrode pattern 7070, the eighth electrode pattern 7080, the ninth electrode pattern 7090, and the tenth electrode pattern 7100 may be spaced apart from each other in the plan view.

The first electrode layer SDL1 may include a metal, an alloy, a metal nitride, a conductive metal oxide, a transparent conductive material, and/or the like. In embodiments, the metal may include silver (Ag), molybdenum (Mo), aluminum (Al), tungsten (W), copper (Cu), nickel (“Ni”), chromium (“Cr”), titanium (“Ti”), tantalum (“Ta”), platinum (“Pt”), scandium (“Sc”), and/or the like. These materials may be used alone or in any combinations with each other. In embodiments, the conductive metal oxide may include Indium tin oxide, indium zinc oxide, and/or the like. These materials may be used alone or in any combinations with each other. In addition, embodiments of the metal nitride may include aluminum nitride (AlNₓ), tungsten nitride (WNₓ), chromium nitride (CrNₓ), and/or the like. These materials may be used alone or in any combinations with each other.

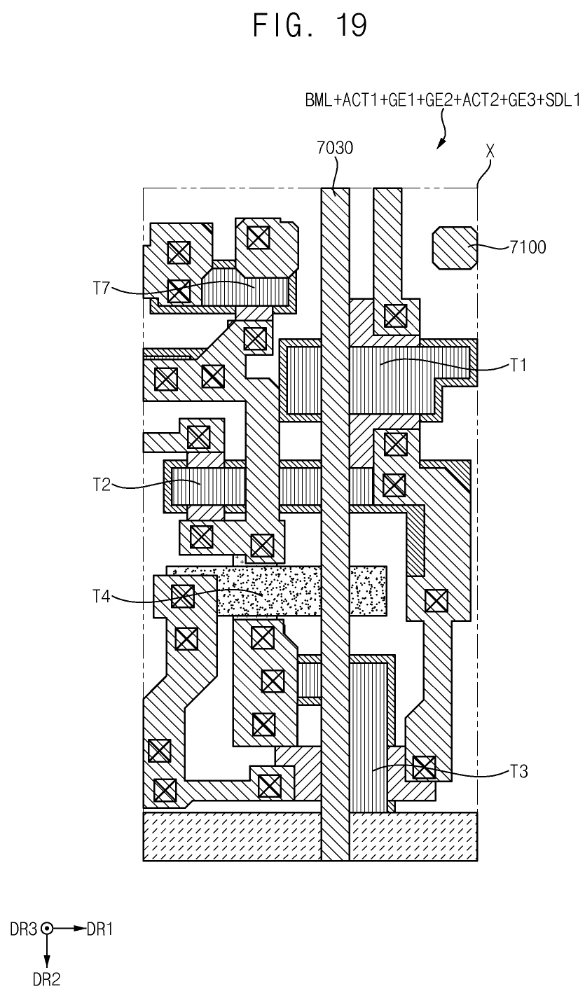

Referring to FIGS. 3 and 19, in embodiments, the third electrode pattern 7030 may correspond to the 1-1 transfer line CA1. In an embodiment, the X area of FIGS. 10-21 may represent a portion of the 4-2 stage 520, and the third electrode pattern 7030 corresponding to the 1-1 transfer line CA1 may cross the 4-2 stage 520 in the plan view, for example. In an embodiment, the third electrode pattern 7030 may extend in the second direction DR2 and cross the 4-2 stage 520 in the plan view, for example.

The third electrode pattern 7030 may at least partially overlap the 4-2 stage 520 in the plan view. In an embodiment, the third electrode pattern 7030 may cross a transistor included in the 4-2 stage 520 in the plan view. In an embodiment, as illustrated in FIG. 19, the third electrode pattern 7030 may cross the first transistor T1 and the third transistor T3 in the plan view, for example. In an embodiment, the third electrode pattern 7030 may at least partially overlap the first transistor T1 in the plan view, for example. In addition, the third electrode pattern 7030 may at least partially overlap the third transistor T3 in the plan view. However, this disclosure is not necessarily limited thereto, and a position of the third electrode pattern 7030 may vary depending on embodiments. In an embodiment, the third electrode pattern 7030 may be disposed to cross the second transistor T2, the fourth transistor T4, or the seventh transistor T7 in the plan view, for example. In an embodiment, although not illustrated in FIG. 19, the third electrode pattern 7030 may also be disposed to cross a capacitor (e.g., the first capacitor CST1 or the second capacitor CST2 of FIG. 9) included in the 4-2 stage 520 in the plan view, for example.

In an embodiment, the third electrode pattern 7030 may cross a lower metal pattern included in the lower metal layer BML in the plan view. In an embodiment, the third electrode pattern 7030 may cross the third lower metal pattern (e.g., the third bottom metal pattern 1030 of FIG. 10) in the plan view, for example. In an embodiment, the third electrode pattern 7030 may at least partially overlap the third lower metal pattern in the plan view, for example. However, this disclosure is not necessarily limited thereto, and the third electrode pattern 7030 may cross a lower metal pattern included in the lower metal layer BML and different from the third electrode pattern 7030 in the plan view.

In an embodiment, in embodiments, the third electrode pattern 7030 may cross an active pattern included in the first active layer ACT1 in the plan view, for example. In an embodiment, the third electrode pattern 7030 may cross the third active pattern (e.g., the third active pattern 2030 of FIG. 11) and the fourth active pattern (e.g., the fourth active pattern 2040 of FIG. 11) in the plan view, for example. In an embodiment, the third electrode pattern 7030 may at least partially overlap the third active pattern in the plan view, for example. In addition, the third electrode pattern 7030 may at least partially overlap the fourth active pattern in the plan view. However, this disclosure is not necessarily limited thereto, and the third electrode pattern 7030 may cross an active pattern included in the first active layer ACT1 and different from the third active pattern and the fourth active pattern in the plan view.

In an embodiment, in embodiments, the third electrode pattern 7030 may cross a gate pattern included in the first gate layer GE1 in the plan view, for example. In an embodiment, the third electrode pattern 7030 may cross the third gate pattern (e.g., the third gate pattern 3030 of FIG. 12), the fourth gate pattern (e.g., the fourth gate pattern 3040 of FIG. 12), and the fifth gate pattern (e.g., the fifth gate pattern 3050 of FIG. 12) in the plan view, for example. In an embodiment, the third electrode pattern 7030 may at least partially overlap the third gate pattern in the plan view. In addition, the third electrode pattern 7030 may at least partially overlap the fourth gate pattern in the plan view, for example. In addition, the third electrode pattern 7030 may at least partially overlap the fifth gate pattern in the plan view. However, this disclosure is not necessarily limited thereto, and the third electrode pattern 7030 may cross a gate pattern included in the first gate layer GE1 and different from the third gate pattern, the fourth gate pattern, and the fifth gate pattern in the plan view.

In an embodiment, in embodiments, the third electrode pattern 7030 may cross a gate pattern included in the second gate layer GE2 in the plan view, for example. In an embodiment, the third electrode pattern 7030 may cross the sixth gate pattern (e.g., the sixth gate pattern 4010 of FIG. 14) and the seventh gate pattern (e.g., the seventh gate pattern 4020 of FIG. 14) in the plan view, for example. In an embodiment, the third electrode pattern 7030 may at least partially overlap the sixth gate pattern in the plan view, for example. In addition, the third electrode pattern 7030 may at least partially overlap the seventh gate pattern in the plan view. However, this disclosure is not necessarily limited thereto, and the third electrode pattern 7030 may cross a gate pattern included in the second gate layer GE2 and different from the sixth gate pattern and the seventh gate pattern in the plan view.

In an embodiment, in embodiments, the third electrode pattern 7030 may cross a gate pattern included in the third gate layer GE3 in the plan view, for example. In an embodiment, the third electrode pattern 7030 may cross the eighth gate pattern (e.g., the eighth gate pattern 6010 of FIG. 16) in the plan view, for example. In an embodiment, the third electrode pattern 7030 may at least partially overlap the eighth gate pattern in the plan view, for example. However, this disclosure is not necessarily limited thereto, and the third electrode pattern 7030 may cross a gate pattern included in the third gate layer GE3 and different from the eighth gate pattern in the plan view.

In an embodiment, the display device may further include a second electrode layer SDL2. In an embodiment, the 4-2 stage may further include the second electrode layer SDL2, for example. The second electrode layer SDL2 may be disposed on the first electrode layer (e.g., the first electrode layer SDL1 of FIG. 19). The second electrode layer SDL2 may include the eleventh electrode pattern 8010, the twelfth electrode pattern 8020, the thirteenth electrode pattern 8030, and the fourteenth electrode pattern 8040. Each of the eleventh electrode pattern 8010, the twelfth electrode pattern 8020, the thirteenth electrode pattern 8030, and the fourteenth electrode pattern 8040 may be spaced apart from each other in the plan view. Each of the eleventh electrode pattern 8010, the twelfth electrode pattern 8020, the thirteenth electrode pattern 8030, and the fourteenth electrode pattern 8040 may extend in the second direction DR2.

In an embodiment, the blocking signal (e.g., the blocking signal ESR of FIG. 9) may be applied to the eleventh electrode pattern 8010, but this disclosure is not necessarily limited thereto. In an embodiment, the second power voltage (e.g., the second power voltage VGL of FIG. 9) may be applied to the twelfth electrode pattern 8020, but this disclosure is not necessarily limited thereto. In an embodiment, the first clock signal (e.g., the first clock signal CLK1 of FIG. 9) or the second clock signal (e.g., the second clock signal CLK2 of FIG. 9) may be applied to the fourteenth electrode pattern 8040, but this disclosure is not necessarily limited thereto.

The second electrode layer SDL2 may include a metal, an alloy, a metal nitride, a conductive metal oxide, a transparent conductive material, and/or the like. In embodiments, the metal may include silver (Ag), molybdenum (Mo), aluminum (Al), tungsten (W), copper (Cu), nickel (“Ni”), chromium (“Cr”), titanium (“Ti”), tantalum (“Ta”), platinum (“Pt”), scandium (“Sc”), and/or the like. These materials may be used alone or in any combinations with each other. In embodiments, the conductive metal oxide may include Indium tin oxide, indium zinc oxide, and/or the like. These materials may be used alone or in any combinations with each other. In addition, embodiments of the metal nitride may include aluminum nitride (AlNₓ), tungsten nitride (WNₓ), chromium nitride (CrNₓ), and/or the like. These materials may be used alone or in any combinations with each other.

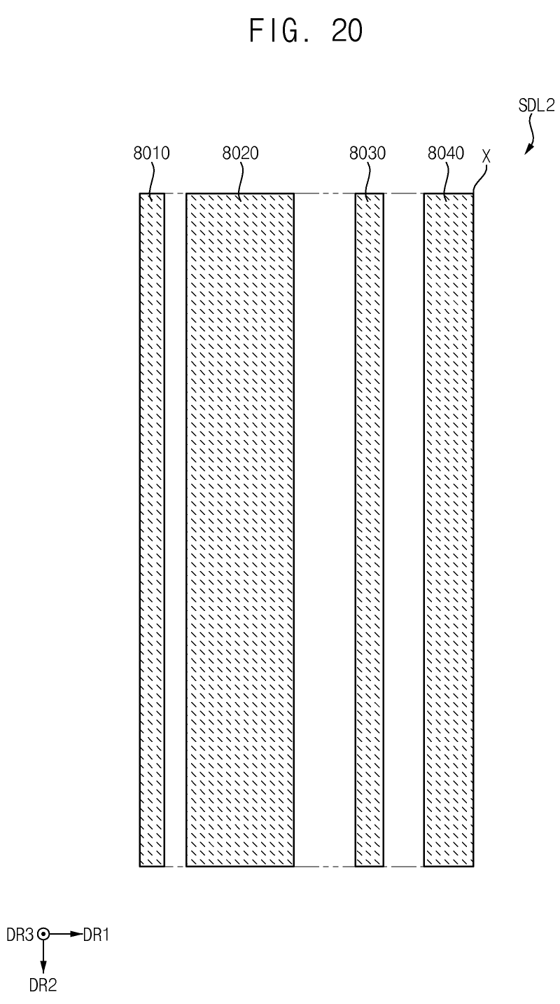

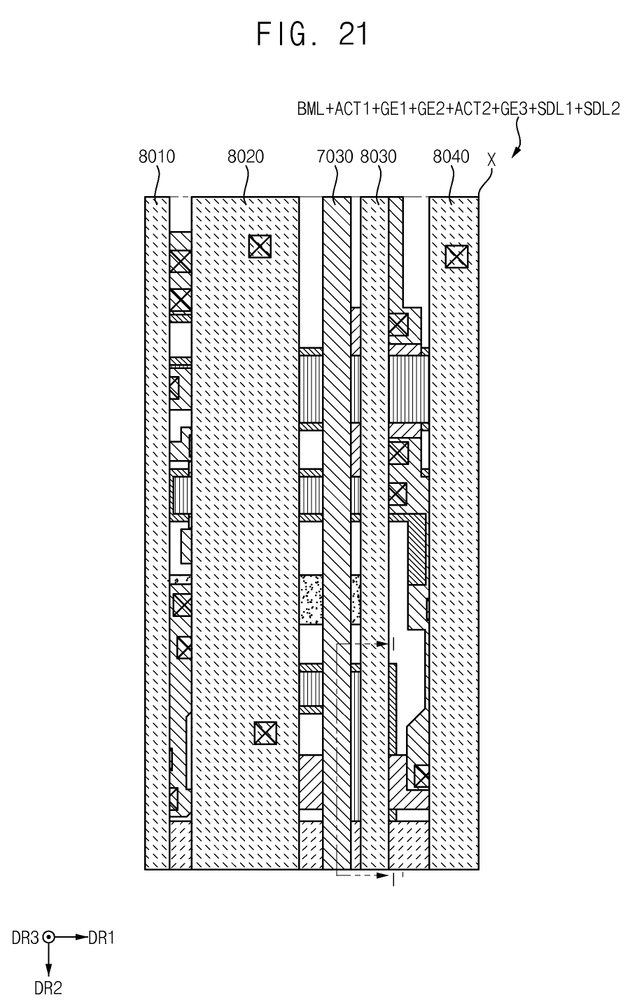

Referring to FIG. 21, in embodiments, the third electrode pattern 7030 may be spaced apart from an electrode pattern included in the second electrode layer SDL2 in the plan view. In an embodiment, the third electrode pattern 7030 may be spaced apart from the eleventh electrode pattern 8010, the twelfth electrode pattern 8020, the thirteenth electrode pattern 8030, and the fourteenth electrode pattern 8040 in the plan view, for example. However, this disclosure is not necessarily limited thereto, and the third electrode pattern 7030 may cross an electrode pattern included in the second electrode layer SDL2 in the plan view. In an embodiment, the third electrode pattern 7030 may cross the twelfth electrode pattern 8020 in the plan view, for example. In an embodiment, the third electrode pattern 7030 may at least partially overlap the twelfth electrode pattern 8020 in the plan view, for example. In addition, although not illustrated in FIGS. 20 and 21, the second electrode layer SDL2 may further include an electrode pattern to which the first power voltage (e.g., the first power voltage VGH of FIG. 9) is applied. In this case, the third electrode pattern 7030 may cross the electrode pattern to which the first power voltage is applied in the plan view. In an embodiment, the third electrode pattern 7030 may at least partially overlap the electrode pattern to which the first power voltage is applied in the plan view, for example.

FIGS. 10-21 may illustrate a layout structure of the 4-2 stage 520, but this disclosure is not necessarily limited thereto. In an embodiment, the 1-1 stage 210, the 1-2 stage 220, the 1-3 stage 230, the 1-4 stage 240, the 2-1 stage 310, the 2-2 stage 320, the 2-3 stage 330, the 2-4 stage 340, the 3-1 stage 410, the 3-2 stage 420, the 3-3 stage 430, the 3-4 stage 440, the 4-1 stage 510, the 4-3 stage 530, and the 4-4 stage 540 of FIG. 2 may have substantially a same structure as that of the layout structure of the 4-2 stage 520 described with reference to FIGS. 10-21, for example.

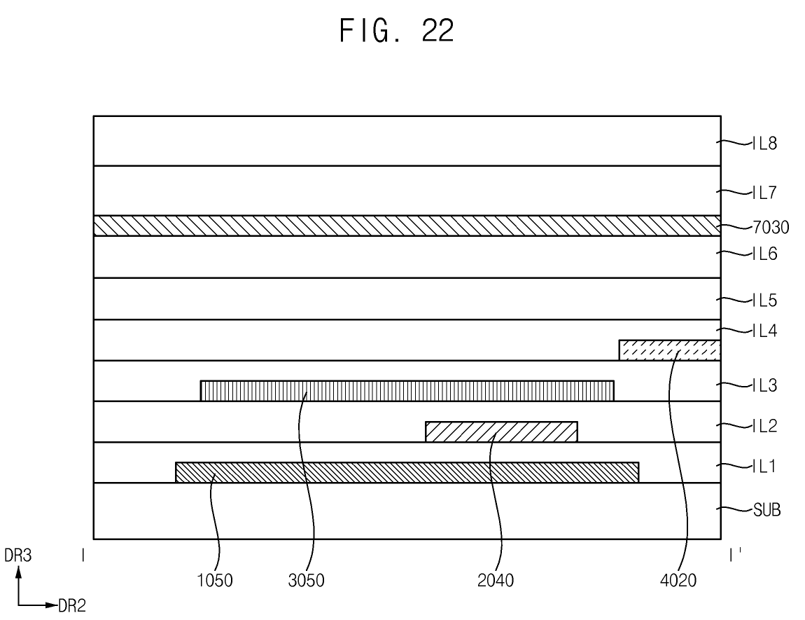

FIG. 22 is a cross-sectional view taken along line I-I` of the display device of FIG. 21.

Referring to FIG. 22, a substrate SUB may include a transparent material or an opaque material. The substrate SUB may include or consist of a transparent resin substrate. Example of the transparent resin substrate may include a polyimide substrate. In this case, the polyimide substrate may include a first organic layer, a first barrier layer, a second organic layer, and/or the like. Optionally, the substrate SUB may include a quartz substrate (e.g. a synthetic quartz substrate, a fluorine-doped quartz substrate), a calcium fluoride substrate, a soda lime glass substrate, a non-alkali glass substrate, and/or the like. These materials may be used alone or in any combinations with each other.

The fifth bottom metal pattern 1050 may be disposed on the substrate SUB. A first insulating layer IL1 may be disposed on the substrate SUB. The first insulating layer IL1 may cover the fifth bottom metal pattern 1050. The first insulating layer IL1 may include inorganic materials such as silicon oxide (“SiOₓ”), silicon nitride (“SiNₓ”), silicon carbide (“SiCₓ”), silicon oxynitride (“SiOₓN_{y}”), silicon oxycarbide (“SiOₓC_{y}”), and/or the like. These materials may be used alone or in any combinations with each other.

The fourth active pattern 2040 may be disposed on the first insulating layer IL1. A second insulating layer IL2 may be disposed on the first insulating layer IL1. The second insulating layer IL2 may cover the fourth active pattern 2040. The second insulating layer IL2 may include inorganic materials such as silicon oxide (“SiOₓ”), silicon nitride (“SiNₓ”), silicon carbide (“SiCₓ”), silicon oxynitride (“SiOₓN_{y}”), silicon oxycarbide (“SiOₓC_{y}”), and/or the like. These materials may be used alone or in any combinations with each other.

The fifth gate pattern 3050 may be disposed on the second insulating layer IL2. A third insulating layer IL3 may be disposed on the second insulating layer IL2. The third insulating layer IL3 may cover the fifth gate pattern 3050. The third insulating layer IL3 may include inorganic materials such as silicon oxide (“SiOₓ”), silicon nitride (“SiNₓ”), silicon carbide (“SiCₓ”), silicon oxynitride (“SiOₓN_{y}”), silicon oxycarbide (“SiOₓC_{y}”), and/or the like. These materials may be used alone or in any combinations with each other.

The seventh gate pattern 4020 may be disposed on the third insulating layer IL3. A fourth insulating layer IL4 may be disposed on the seventh gate pattern 4020. The fourth insulating layer IL4 may cover the seventh gate pattern 4020. The fourth insulating layer IL4 may include inorganic materials such as silicon oxide (“SiOₓ”), silicon nitride (“SiNₓ”), silicon carbide (“SiCₓ”), silicon oxynitride (“SiOₓN_{y}”), silicon oxycarbide (“SiOₓC_{y}”), and/or the like. These materials may be used alone or in any combinations with each other.

The second active layer (e.g., the second active layer ACT2 of FIG. 15) may be disposed on the fourth insulating layer IL4. A fifth insulating layer IL5 may be disposed on the fourth insulating layer IL4. The fifth insulating layer IL5 may cover the second active layer. The fifth insulating layer IL5 may include inorganic materials such as silicon oxide (“SiOₓ”), silicon nitride (“SiNₓ”), silicon carbide (“SiCₓ”), silicon oxynitride (“SiOₓN_{y}”), silicon oxycarbide (“SiOₓC_{y}”), and/or the like. These materials may be used alone or in any combinations with each other.

The third gate layer (e.g., the third gate layer GE3 of FIG. 16) may be disposed on the fifth insulating layer IL5. A sixth insulating layer IL6 may be disposed on the fifth insulating layer IL5. The sixth insulating layer IL6 may cover the third gate layer. The sixth insulating layer IL6 may include inorganic materials such as silicon oxide (“SiOₓ”), silicon nitride (“SiNₓ”), silicon carbide (“SiCₓ”), silicon oxynitride (“SiOₓN_{y}”), silicon oxycarbide (“SiOₓC_{y}”), and/or the like. These materials may be used alone or in any combinations with each other.

The third electrode pattern 7030 may be disposed on the sixth insulating layer IL6. The third electrode pattern 7030 may at least partially overlap the fifth bottom metal pattern 1050 in the plan view. The third electrode pattern 7030 may at least partially overlap the fourth active pattern 2040 in the plan view. The third electrode pattern 7030 may at least partially overlap the fifth gate pattern 3050 in the plan view. The third electrode pattern 7030 may at least partially overlap the seventh gate pattern 4020 in the plan view.

A seventh insulating layer IL7 may be disposed on the sixth insulating layer IL6. The seventh insulating layer IL7 may cover the third electrode pattern 7030. In an embodiment, the seventh insulating layer IL7 may include an organic material such as phenolic resin, acryl resin, polyimides resin, polyamides resin, siloxane resin, epoxy resin, and/or the like. These materials may be used alone or in any combinations with each other. In an embodiment, the seventh insulating layer IL7 may further include inorganic materials such as silicon oxide (“SiOₓ”), silicon nitride (“SiNₓ”), silicon carbide (“SiCₓ”), silicon oxynitride (“SiOₓN_{y}”), silicon oxycarbide (“SiOₓC_{y}”), and/or the like. These materials may be used alone or in any combinations with each other.

An eighth insulating layer IL8 may be disposed on the seventh insulating layer IL7. The eighth insulating layer IL8 may cover the second electrode layer (e.g., the second electrode layer SDL2 of FIG. 21). In an embodiment, the eighth insulating layer IL8 may include an organic material such as phenolic resin, acryl resin, polyimides resin, polyamides resin, siloxane resin, epoxy resin, and/or the like. These materials may be used alone or in any combinations with each other. In an embodiment, the eighth insulating layer IL8 may further include inorganic materials such as silicon oxide (“SiOₓ”), silicon nitride (“SiNₓ”), silicon carbide (“SiCₓ”), silicon oxynitride (“SiOₓN_{y}”), silicon oxycarbide (“SiOₓC_{y}”), and/or the like. These materials may be used alone or in any combinations with each other.

FIG. 23 is a circuit diagram illustrating a pixel included in the display device of FIG. 1.

Referring to FIG. 23, the pixel PX may include a pixel driving circuit portion PXC and a light-emitting element LED electrically connected to the pixel driving circuit portion PXC. In an embodiment, the pixel driving circuit portion PXC may include a first pixel transistor PT1, a second pixel transistor PT2, a third pixel transistor PT3, a fourth pixel transistor PT4, a fifth pixel transistor PT5, a sixth pixel transistor PT6, a seventh pixel transistor PT7, an eighth pixel transistor PT8, a first pixel capacitor PCST1, and a second pixel capacitor PCST2.

In an embodiment, each of the first pixel transistor PT1, the second pixel transistor PT2, the fifth pixel transistor PT5, the sixth pixel transistor PT6, the seventh pixel transistor PT7, and the eighth pixel transistor PT8 may be a PMOS transistor, and each of the third pixel transistor PT3 and the fourth pixel transistor PT4 may be an NMOS transistor, but this disclosure is not necessarily limited thereto.

In an embodiment, the first pixel transistor PT1 may include a first electrode connected to a first node PN1, a gate electrode connected to a second node PN2, and a second electrode connected to a third node PN3.

The second pixel transistor PT2 may include a first electrode connected to a fourth node PN4, a gate electrode that receives a gate write signal GW, and a second electrode connected to the first node PN1. The first electrode of the second pixel transistor PT2 may receive a data voltage DT through the fourth node PN4.

The third pixel transistor PT3 may include a first electrode connected to a fifth node PN5, a gate electrode that receives a gate compensation signal GC, and a second electrode connected to the third node PN3.

The fourth pixel transistor PT4 may include a first electrode that receives a first initialization voltage VINT, a gate electrode that receives a gate initialization signal GI, and a second electrode connected to a fifth node PN5.

The fifth pixel transistor PT5 may include a first electrode connected to a sixth node PN6, a gate electrode that receives a light-emitting control signal EM, and a second electrode connected to the first node PN1. The first electrode of the fifth pixel transistor PT5 may receive a first pixel power voltage ELVDD through the sixth node PN6.

The sixth pixel transistor PT6 may include a first electrode connected to the third node PN3, a gate electrode that receives the light-emitting control signal EM, and a second electrode connected to a seventh node PN7.

The seventh pixel transistor PT7 may include a first electrode that receives a second initialization voltage VAINT, a gate electrode that receives a gate bias signal GB, and a second electrode connected to the seventh node PN7.

The eighth pixel transistor PT8 may include a first electrode connected to an eighth node PN8, a gate electrode that receives a gate bias signal GB, and a second electrode connected to the first node PN1. The first electrode of the eighth pixel transistor PT8 may receive a bias voltage VOBS through the eighth node PN8.

The first pixel capacitor PCST1 may include a first electrode and a second electrode. The first electrode of the first pixel capacitor PCST1 may be connected to a ninth node PN9. The second electrode of the first pixel capacitor PCST1 may be connected to the second node PN2. The first electrode of the first pixel capacitor PCST1 may receive the first pixel power voltage ELVDD through the ninth node PN9.

The second pixel capacitor PCST2 may include a first electrode and a second electrode. The first electrode of the second pixel capacitor PCST2 may be connected to the seventh node PN7. The second electrode of the second pixel capacitor PCST2 may be connected to a tenth node PN10. The second electrode of the second pixel capacitor PCST2 may receive a second pixel power voltage ELVSS through the tenth node PN10.

The light-emitting element LED may include a first electrode and a second electrode. The first electrode of the light-emitting element LED may be connected to the seventh node PN7. The second electrode of the light-emitting element LED may be connected to the tenth node PN10. The second electrode of the light-emitting element LED may receive the second pixel power voltage ELVSS through the tenth node PN10. In an embodiment, the first electrode of the light-emitting element LED may be an anode electrode, and the second electrode of the light-emitting element LED may be a cathode electrode, but this disclosure is not necessarily limited thereto.

As illustrated in FIG. 23, the pixel driving circuit portion PXC may include eight transistors and two capacitors. However, this disclosure is not necessarily limited thereto, and the number of transistors and the number of capacitors included in the pixel driving circuit portion PXC may vary depending on embodiments.

In addition, as described above, the first driver (e.g., the first driver 200 of FIG. 2) may output the light-emitting control signal EM to the display area (e.g., the display area DA of FIG. 2), the second driver (e.g., the second driver 300 of FIG. 2) may output the gate initialization signal GI to the display area, the third driver (e.g., the third driver 400 of FIG. 2) may output the gate compensation signal GC to the display area, and the fourth driver (e.g., the fourth driver 500 of FIG. 2) may output the gate bias signal GB to the display area. Although FIG. 23 illustrates the gate write signal GW applied to the gate electrode of the second pixel transistor PT2, for convenience of description, a driver for outputting the gate write signal GW to the display area may be omitted in FIGS. 2-8.

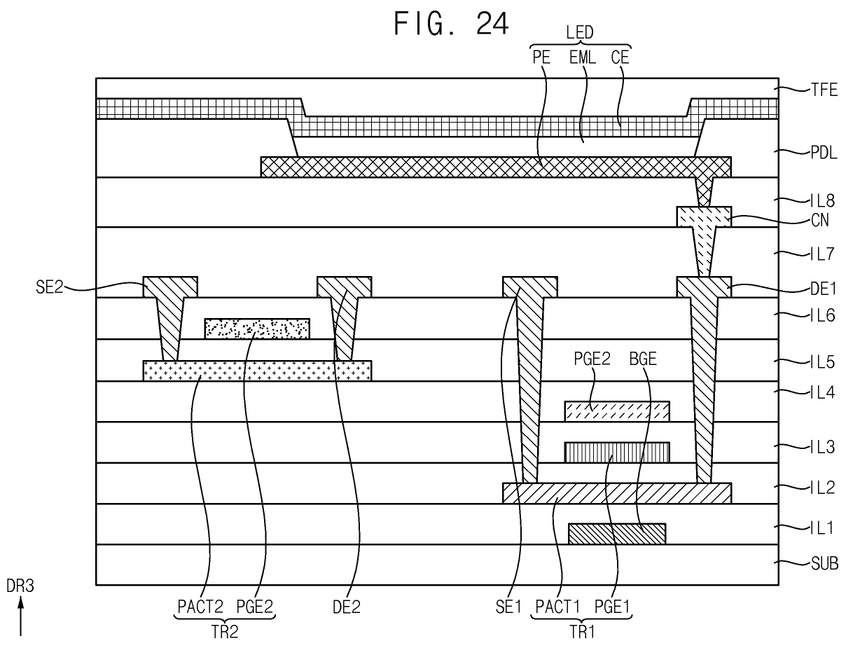

FIG. 24 is a cross-sectional view illustrating a portion of the pixel included in the display device of FIG. 1.

Referring to FIG. 24, the pixel (e.g., the pixel PX of FIG. 1) may include the substrate SUB, a lower metal pattern BGE, a lower transistor TR1, an upper transistor TR2, a second gate electrode GE2, a first contact electrode SE1, a second contact electrode DE1, a third contact electrode SE2, a fourth contact electrode DE2, a fifth contact electrode CN, the first insulating layer IL1, the second insulating layer IL2, the third insulating layer IL3, the fourth insulating layer IL4, the fifth insulating layer IL5, the sixth insulating layer IL6, the seventh insulating layer IL7, the eighth insulating layer IL8, a pixel defining layer PDL, a light-emitting element LED, and an encapsulation layer TFE.

The lower transistor TR1 may include a lower active pattern PACT1 and a first gate electrode PGE1. The upper transistor TR2 may include an upper active pattern PACT2 and a third gate electrode PGE3. The upper transistor TR2 may be disposed on the lower transistor TR1. The light-emitting element LED may include a pixel electrode PE, a light-emitting layer EML, and a common electrode CE.

The lower metal pattern BGE may be disposed on the substrate SUB. The lower metal pattern BGE and the lower metal layer (e.g., the lower metal layer BML of FIG. 10) may be formed through substantially a same process. The lower metal pattern BGE and the lower metal layer may include substantially a same material as each other. The lower metal pattern BGE and the lower metal layer may be disposed in substantially a same layer. The first insulating layer IL1 may cover the lower metal pattern BGE.

The lower active pattern PACT1 may be disposed on the first insulating layer IL1. The lower active pattern PACT1 and the first active layer (e.g., the first active layer ACT1 of FIG. 11) may be formed through substantially a same process. The lower active pattern PACT1 and the first active layer may include substantially a same material as each other. The lower active pattern PACT1 and the first active layer may be disposed in substantially a same layer. The second insulating layer IL2 may cover the lower active pattern PACT1.

The first gate electrode PGE1 may be disposed on the second insulating layer IL2. The first gate electrode PGE1 and the first gate layer (e.g., the first gate layer GE1 of FIG. 12) may be formed through substantially a same process. The first gate electrode PGE1 and the first gate layer may include substantially a same material as each other. The first gate electrode PGE1 and the first gate layer may be disposed in substantially a same layer. The third insulating layer IL3 may cover the first gate electrode PGE1.

The second gate electrode PGE2 may be disposed on the third insulating layer IL3. The second gate electrode PGE2 and the second gate layer (e.g., the second gate layer GE2 of FIG. 14) may be formed through substantially a same process. The second gate electrode PGE2 and the second gate layer may include substantially a same material as each other. The second gate electrode PGE2 and the second gate layer may be disposed in substantially a same layer. The fourth insulating layer IL4 may cover the second gate electrode PGE2.

The upper active pattern PACT2 may be disposed on the fourth insulating layer IL4. The upper active pattern PACT2 and the second active layer (e.g., the second active layer ACT2 of FIG. 15) may be formed through substantially a same process. The upper active pattern PACT2 and the second active layer may include substantially a same material as each other. The upper active pattern PACT2 and the second active layer may be disposed in substantially a same layer. The fifth insulating layer IL5 may cover the upper active pattern PACT2.

The third gate electrode PGE3 may be disposed on the fifth insulating layer IL5. The third gate electrode PGE3 and the third gate layer (e.g., the third gate layer GE3 of FIG. 16) may be formed through substantially a same process. The third gate electrode PGE3 and the third gate layer may include substantially a same material as each other. The third gate electrode PGE3 and the third gate layer may be disposed in substantially a same layer. The sixth insulating layer IL6 may cover the third gate electrode PGE3.

The first contact electrode SE1, the second contact electrode DE1, the third contact electrode SE2, and the fourth contact electrode DE2 may be disposed on the sixth insulating layer IL6. The first contact electrode SE1 may be electrically connected to a portion of the lower active pattern PACT1 through a contact hole penetrating (or, defined through) the second insulating layer IL2, the third insulating layer IL3, the fourth insulating layer IL4, the fifth insulating layer IL5, and the sixth insulating layer IL6. The second contact electrode DE1 may be connected to a portion of the lower active pattern PACT1 through a contact hole penetrating (or, defined through) the second insulating layer IL2, the third insulating layer IL3, the fourth insulating layer IL4, the fifth insulating layer IL5, and the sixth insulating layer IL6. The third contact electrode SE2 may be connected to a portion of the upper active pattern PACT2 through a contact hole penetrating (or, defined through) the fifth insulating layer IL5 and the sixth insulating layer IL6. The fourth contact electrode DE2 may be connected to a portion of the upper active pattern PACT2 through a contact hole penetrating (or, defined through) the fifth insulating layer IL5 and the sixth insulating layer IL6.

The first contact electrode SE1, the second contact electrode DE1, the third contact electrode SE2, the fourth contact electrode DE2, and the first electrode layer (e.g., the first electrode layer SDL1 of FIG. 18) may be formed through substantially a same process. The first contact electrode SE1, the second contact electrode DE1, the third contact electrode SE2, the fourth contact electrode DE2, and the first electrode layer may include substantially a same material as each other. The first contact electrode SE1, the second contact electrode DE1, the third contact electrode SE2, the fourth contact electrode DE2, and the first electrode layer may be disposed in substantially a same layer. The seventh insulating layer IL7 may cover the first contact electrode SE1, the second contact electrode DE1, the third contact electrode SE2, and the fourth contact electrode DE2.

The fifth contact electrode CN may be disposed on the seventh insulating layer IL7. The fifth contact electrode CN may be connected to the second contact electrode DE1 through a contact hole penetrating (or, defined through) the seventh insulating layer IL7. The fifth contact electrode CN and the second electrode layer (e.g., the second electrode layer SDL2 of FIG. 20) may be formed through substantially a same process. The fifth contact electrode CN and the second electrode layer may include substantially a same material as each other. The fifth contact electrode CN and the second electrode layer may be disposed in substantially a same layer. The eighth insulating layer IL8 may cover the fifth contact electrode CN.

The pixel electrode PE may be disposed on the eighth insulating layer IL8. The pixel electrode PE may be connected to the fifth contact electrode CN through a contact hole penetrating (or, defined through) the eighth insulating layer IL8. The pixel electrode PE may include metal, alloy, metal nitride, conductive metal oxide, transparent conductive material, and/or the like. These materials may be used alone or in any combinations with each other. In an embodiment, the pixel electrode PE may have a stacked structure including ITO/Ag/ITO, but this disclosure is not necessarily limited thereto. The pixel electrode PE may be an anode electrode of the light-emitting element LED.

The pixel defining layer PDL may be disposed on the eighth insulating layer IL8. The pixel defining layer PDL may cover a side portion of the pixel electrode PE. In an embodiment, a pixel opening exposing a portion of an upper surface of the pixel electrode PE may be defined in the pixel defining layer PDL, for example. In an embodiment, the pixel defining layer PDL may include an inorganic material or an organic material, for example. In an embodiment, the pixel defining layer PDL may include an organic material such as epoxy resin, siloxane resin, and/or the like. These materials may be used alone or in any combinations with each other. In an embodiment, the pixel defining layer PDL may further include a light-blocking material including or consisting of black pigment, black dye, and/or the like.

The light-emitting layer EML may be disposed on the pixel electrode PE. The light-emitting layer EML may include an organic material that emits light of a selected color.

The common electrode CE may be disposed on the light-emitting layer EML. The common electrode CE may include a metal, an alloy, a metal nitride, a conductive metal oxide, a transparent conductive material, and/or the like. These materials may be used alone or in any combinations with each other. The common electrode CE may be a cathode electrode of the light-emitting element LED.

The encapsulation layer TFE may be disposed on the common electrode CE. The encapsulation layer TFE may prevent impurities, moisture, and/or the like from penetrating into the light-emitting element LED from an outside. In an embodiment, the encapsulation layer TFE may include at least one inorganic encapsulation layer and at least one organic encapsulation layer, for example. In an embodiment, the inorganic encapsulation layer and the organic encapsulation layer may be alternately stacked, for example. In an embodiment, the inorganic encapsulation layer may include silicon oxide, silicon nitride, silicon oxynitride, and/or the like, for example. These materials may be used alone or in any combinations with each other. The organic encapsulation layer may include a polymer cured material such as polyacrylate.

In an embodiment, the lower transistor TR1 may substantially correspond to the sixth pixel transistor PT6 or the seventh pixel transistor PT7 of FIG. 23, but this disclosure is not necessarily limited thereto. In an embodiment, the upper transistor TR2 may substantially correspond to the third pixel transistor PT3 or the fourth pixel transistor PT4 of FIG. 23, but this disclosure is not necessarily limited thereto.

The display device (e.g., the display device DD of FIG. 1) in embodiments may be applied to various electronic devices. An electronic device in embodiments may include the above-described display device, and may further include a module or device having other additional functions in addition to the display device.

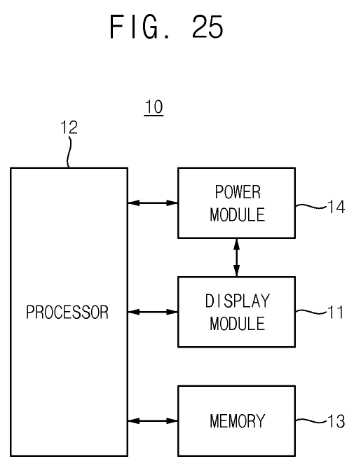

FIG. 25 is a block diagram illustrating an electronic device.

Referring to FIG. 25, an electronic device 10 in embodiments may include a display module 11, a processor 12, a memory 13, and a power module 14.

The processor 12 may include at least one of a central processing unit (“CPU”), an application processor (“AP”), a graphic processing unit (“GPU”), a communication processor (“CP”), an image signal processor (“ISP”), and a controller.

Data information desired for operation of the processor 12 or the display module 11 may be stored in the memory 13. When the processor 12 executes an application stored in the memory 13, an image data signal and/or an input control signal is transmitted to the display module 11, and the display module 11 may process received signal and output image information through a display screen.

The power module 14 may include a power supply module such as a power adapter or a battery device, and a power conversion module that converts power supplied by the power supply module to generate power desired for operation of the electronic device 10.

At least one of components of the electronic device 10 described above may be included in the display device according to the above-described embodiments. In addition, some of individual modules functionally included in one module may be included in the display device, and others may be provided separately from the display device. In an embodiment, the display device may include the display module 11, and the processor 12, the memory 13, and the power module 14 may be provided in form of another device in the electronic device 10 other than the display device, for example.

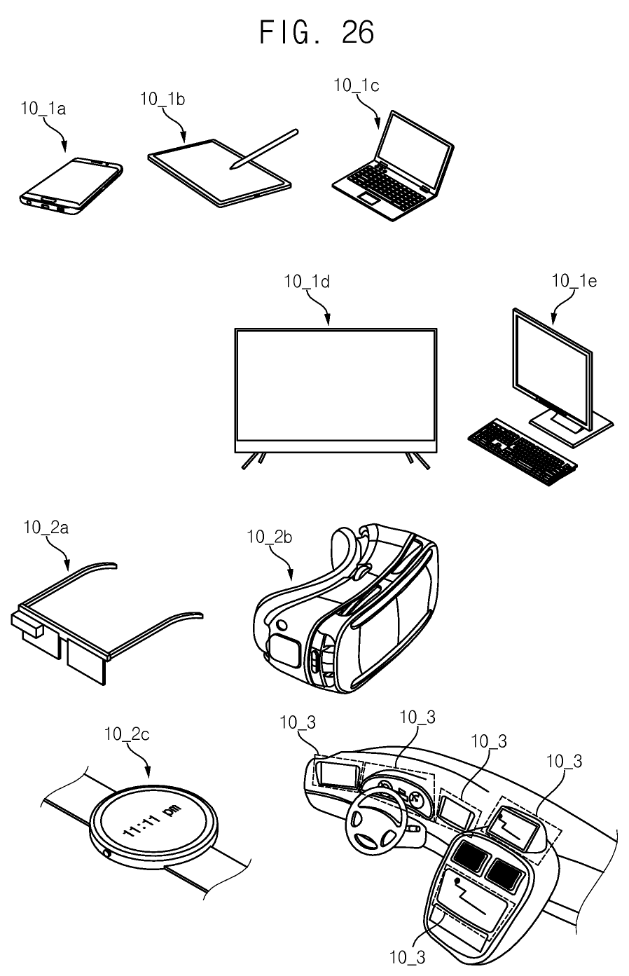

FIG. 26 is a schematic diagram of embodiments of an electronic device.

Referring to FIG. 26, various electronic devices to which display devices in embodiments are applied may include not only electronic devices for image display such as a smartphone 10-1a, a tablet personal computer (“PC”) 10-1b, a laptop 10-1c, a television (“TV”) 10-1d, a desk monitor 10-1e, and/or the like, but also wearable electronic devices including display modules such as a smart glass 10-2a, a head mounted display 10-2b, a smart watch 10-2c, and/or the like, vehicle electronic device 10-3 including display modules such as a vehicle's instrument panel, a center fascia, a center information display (“CID”) disposed on a dashboard, a room mirror display, and/or the like.

The disclosure may be applied to various display devices. In an embodiment, the disclosure is applicable to various display devices such as display devices for vehicles, ships and aircraft, portable communication devices, display devices for exhibition or information transmission, medical display devices, or the like, for example.

The foregoing is illustrative of embodiments and is not to be construed as limiting thereof. Although a few embodiments have been described, those skilled in the art will readily appreciate that many modifications are possible in the embodiments without materially departing from the novel teachings and advantages of the inventive concept. Accordingly, all such modifications are intended to be included within the scope of the inventive concept as defined in the claims. Therefore, it is to be understood that the foregoing is illustrative of various embodiments and is not to be construed as limited to the illustrative embodiments disclosed, and that modifications to the disclosed embodiments, as well as other embodiments, are intended to be included within the scope of the appended claims.

What is claimed is:

1. A display device comprising:
a pixel disposed in a display area;
a 1-1 stage disposed at one side of the display area in a plan view;
a 4-2 stage disposed at the one side of the display area in the plan view;
a 1-3 stage disposed at the one side of the display area in the plan view; and
a 1-1 transfer line crossing the 4-2 stage in the plan view,
wherein the 1-3 stage receives a 1-1 signal from the 1-1 stage through the 1-1 transfer line.

2. The display device of claim 1, further comprising:
a 1-2 stage disposed at an opposite side of the display area in the plan view;
a 4-1 stage disposed at the opposite side of the display area which is opposite to the one side of the display area in the plan view; and
a 4-3 stage disposed at the opposite side of the display area in the plan view,
wherein the 4-3 stage receives a 4-1 signal from the 4-1 stage through a 4-1 transfer line crossing the 1-2 stage in the plan view.

3. The display device of claim 1, wherein the 1-1 stage outputs the 1-1 signal to the pixel.

4. The display device of claim 1, wherein the 1-1 transfer line at least partially overlaps a transistor included in the 4-2 stage in the plan view.

5. The display device of claim 1, wherein the 4-2 stage includes,
a lower metal layer;
a first active layer disposed on the lower metal layer;
a first gate layer disposed on the first active layer; and
a second gate layer disposed on the first gate layer, and
the 1-1 transfer line is disposed on the second gate layer.

6. The display device of claim 5, wherein the 1-1 transfer line crosses a lower metal pattern included in the lower metal layer in the plan view.

7. The display device of claim 5, wherein the 1-1 transfer line crosses an active pattern included in the first active layer in the plan view.

8. The display device of claim 5, wherein the 1-1 transfer line crosses a gate pattern included in the first gate layer in the plan view.

9. The display device of claim 5, wherein the 1-1 transfer line crosses a gate pattern included in the second gate layer in the plan view.

10. The display device of claim 5, further comprising:
a second active layer disposed on the second gate layer; and
a third gate layer disposed on the second active layer, and
the 1-1 transfer line is disposed on the third gate layer.

11. The display device of claim 10, wherein the 1-1 transfer line crosses a portion of gate patterns included in the third gate layer in the plan view.

12. The display device of claim 1, wherein the 4-2 stage is disposed between the 1-1 stage and the 1-3 stage.

13. The display device of claim 1, wherein the 1-1 stage and the 4-2 stage are disposed along a second direction, and
the 1-1 transfer line extends in the second direction.

14. A display device comprising:
a pixel disposed in a display area, the pixel including:
a lower active pattern;
a first gate electrode disposed on the lower active pattern;
a second gate electrode disposed on the first gate electrode;
an upper active pattern disposed on the second gate electrode; and
a third gate electrode disposed on the upper active pattern;
a 1-1 stage disposed at one side of the display area in a plan view;
a 4-2 stage disposed at the one side of the display area in the plan view;
a 1-3 stage disposed at the one side of the display area in the plan view; and
a 1-1 transfer line crossing the 4-2 stage in the plan view,
wherein the 1-3 stage receives a 1-1 signal from the 1-1 stage through the 1-1 transfer line.

15. The display device of claim 14, the 4-2 stage includes,
a first active layer disposed in a same layer as the lower active pattern;
a first gate layer disposed in a same layer as the first gate electrode;
a second gate layer disposed in a same layer as the second gate electrode; and
a third gate layer disposed in a same layer as the third gate electrode, and
the 1-1 transfer line is disposed on the third gate layer.

16. The display device of claim 15, wherein the 1-1 transfer line crosses an active pattern included in the first active layer in the plan view.

17. The display device of claim 15, wherein the 1-1 transfer line crosses a gate pattern included in the first gate layer in the plan view.

18. The display device of claim 15, wherein the 1-1 transfer line crosses a gate pattern included in the second gate layer in the plan view.

19. The display device of claim 15, wherein the 1-1 transfer line crosses a gate pattern included in the third gate layer in the plan view.

20. An electronic device comprising:
a pixel disposed in a display area;
a 1-1 stage disposed at one side of the display area in a plan view;
a 4-2 stage disposed at the one side of the display area in the plan view;
a 1-3 stage disposed at the one side of the display area in the plan view;
a display module which receives a data signal and a control signal from a processor; and
a 1-1 transfer line crossing the 4-2 stage in the plan view,
wherein
the 1-3 stage receives a 1-1 signal from the 1-1 stage through the 1-1 transfer line, and
the 1-1 signal is output to the pixel.
